(19) United States
(12) Patent Application Publication
(10) Pub. No.: US 2024/0324327 A1
(43) Pub. Date: Sep. 26, 2024

(54) DISPLAY DEVICE AND METHOD OF MANUFACTURING THE SAME

(71) Applicant: Samsung Display Co., LTD., Yongin-si (KR)

(72) Inventors: SANGDUK LEE, Yongin-si (KR); HOIKWAN LEE, Yongin-si (KR); EUN-KYUNG YEON, Yongin-si (KR)

(21) Appl. No.: 18/440,290

(22) Filed: Feb. 13, 2024

(30) Foreign Application Priority Data
Mar. 22, 2023 (KR) 10-2023-0037132

(51) Int. Cl. H10K 59/126; G06F 1/16; H10K 59/12; H10K 59/80

(52) U.S. Cl. CPC H10K 59/126; G06F 1/1652; H10K 59/1201; H10K 59/873

(57) ABSTRACT

Provided is a display device including a display panel including a non-bending region and a bending region that extends from an end of the non-bending region and that is bent, a protective layer disposed on a lower surface of the display panel, a light blocking pattern overlapping the bending region in a plan view, partially disposed on an upper surface of the display panel, and contacting with a side surface of the protective layer and the bending region, and a coating window disposed directly on the light blocking pattern and including a resin material.

### REFERENCE TO RELATED APPLICATIONS

This application claims priority to Korean Patent Application No. 10-2023-0037132, filed on Mar. 22, 2023, and all the benefits accruing therefrom under 35 U.S.C. § 119, the content of which in its entirety is herein incorporated by reference.

### BACKGROUND

### 1. Field

The present invention herein relates to a display device and a manufacturing method thereof, and more particularly, to a display device including a light blocking pattern and a coating window.

### 2. Description of Related Art

Display devices such as televisions, monitors, smart phones, and tablets, which provide images to users, include a display panel configured to display images. As such, various display panels such as a liquid crystal display panel, an organic light-emitting display panel, an electro-wetting display panel, and an electrophoretic display panel are being developed. In addition, a display device may include a window for protecting the display panel. The window may be attached to the display panel through a lamination process.

### SUMMARY

The present invention provides a display device including a light blocking pattern and a coating window.

The present invention also provides a method for manufacturing a display device including a light blocking pattern and a coating window.

An embodiment of the invention provides a display device including a display panel including a non-bending region and a bending region that extends from an end of the non-bending region and is bent, a protective layer disposed on a lower surface of the display panel, a light blocking pattern overlapping the bending region in a plan view, partially disposed on an upper surface of the display panel, and contacting with a side surface of the protective layer and the bending region and a coating window disposed directly on the light blocking pattern and including a resin material.

In an embodiment, the light blocking pattern may cover a bent portion of the bending region.

In an embodiment, the light blocking pattern may include a first light blocking pattern disposed between the bending region and a side surface of the protective layer and a second light blocking pattern disposed on the bending region and adjacent to the outside of the bending region.

In an embodiment, the display device further includes an optical unit disposed between the display panel and the coating window and overlapping the non-bending region, and the coating window may be disposed directly on the optical unit.

In an embodiment, a portion of the light blocking pattern may be disposed directly on the optical unit.

In an embodiment, the display device further includes a bending protective layer, which is disposed on the display panel and bent together with the bending region, and the light blocking pattern may come in contact with the bending protective layer.

In an embodiment, the light blocking pattern may cover a side surface of the display panel on a cross section.

In an embodiment, the light blocking pattern may include a lower light blocking pattern contacting with the bending region and a side surface of the protective layer and an upper light blocking pattern disposed above the lower light blocking pattern and including a material different from that of the lower light blocking pattern.

In an embodiment, the coating window may include a first coating window directly disposed between the lower light blocking pattern and the upper light blocking pattern and having a first modulus value and a second coating window disposed directly on the upper light blocking pattern and the first coating window and having a second modulus value greater than the first modulus value.

In an embodiment, a display device may include a display panel including a display region and a non-display region surrounding the display region, a first circuit board connected to the display panel and bent, a protective layer disposed on a lower surface of the display panel, a light blocking pattern overlapping a bent portion of the first circuit board in a plan view, partially disposed on an upper surface of the display panel, and contacting with a side surface of the protective layer and a bent portion of the first circuit board and a coating window disposed directly on the light blocking pattern and containing a resin material.

In an embodiment, the light blocking pattern may cover the bent portion of the first circuit board.

In an embodiment, the light blocking pattern may cover a side surface of the display panel on a cross section.

In an embodiment, the display device may further include a touch sensing panel disposed on the display panel and configured to sense an input signal and a second circuit board which is bent, connected to the touch sensing panel, and configured to transmit the input signal.

In an embodiment, the light blocking pattern may include a first light blocking pattern disposed between a side surface of the protective layer and the first circuit board a second light blocking pattern disposed between the first circuit board and the second circuit board and a third light blocking pattern disposed on the second circuit board and disposed adjacent to an outside of the second circuit board.

In an embodiment, a method for manufacturing a display device may include preparing a preliminary display device including a display panel and a protective layer disposed on a lower surface of the display panel, bending the display panel or a first circuit board coupled to the display panel, disposing a bent preliminary display device on a jig, forming a light blocking pattern contacting with a side surface of the protective layer, partially disposed on an upper surface of the display panel, and contacting with the bent display panel or the bent first circuit board, providing a resin material on the light blocking pattern and forming a first coating window by curing the resin material.

In an embodiment, the forming of the light blocking pattern may include making a filling with a light blocking material which comes in contact with the bent display panel or the bent first circuit board and curing the light blocking material.

In an embodiment, a step difference corresponding to a side surface of the coating window may be defined on one side surface of the jig.

In an embodiment, the jig may contain a material that allows ultraviolet rays to pass therethrough.

In an embodiment, the forming of the light blocking pattern may include forming a lower light blocking pattern contacting with the bent display panel or the bent first circuit board and forming an upper light blocking pattern disposed above the lower light blocking pattern and containing a material different from that of the lower light blocking pattern.

In an embodiment, the method may further include forming a second coating window, which has a lower modulus value than the first coating window, on the lower light blocking pattern.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. The above and other objects and features of the invention will become apparent by describing in detail embodiments thereof with reference to the accompanying drawings. In the drawings:

FIG. 1 is a perspective view of a display device, according to an embodiment;

FIG. 2A is an exploded perspective view of the display device, according to an embodiment;

FIG. 2B is an exploded perspective view of the display device, according to an embodiment;

FIG. 3 is a plan view of a display panel, according to an embodiment;

FIG. 4 is a plan view of a light blocking pattern, according to an embodiment;

FIG. 5A is a side view of the display device, according to an embodiment;

FIG. 5B is a side view of the display device, according to an embodiment;

FIG. 6 is a side view of the display device, according to an embodiment;

FIG. 7 is a side view of the display device, according to an embodiment;

FIG. 8A is an exploded perspective view of the display device, according to an embodiment;

FIG. 8B is an exploded perspective view of the display device, according to an embodiment;

FIG. 9 is a plan view of the display panel, according to an embodiment;

FIG. 10 is a plan view of a touch sensing panel, according to an embodiment;

FIG. 11 is a plan view of the light blocking pattern, according to an embodiment;

FIG. 12A is a side view of the display device, according to an embodiment;

FIG. 12B is a side view of the display device, according to an embodiment;

FIG. 13 is a side view of the display device, according to an embodiment;

FIG. 14 is a side view of the display device, according to an embodiment;

FIG. 15A is a side view illustrating a method of manufacturing a display device, according to an embodiment;

FIG. 15B is a side view illustrating a method of manufacturing a display device, according to an embodiment;

FIG. 15C is a side view illustrating a method of manufacturing a display device, according to an embodiment;

FIG. 15D is a side view illustrating a method of manufacturing a display device, according to an embodiment;

FIG. 15E is a side view illustrating a method of manufacturing a display device, according to an embodiment;

FIG. 15F is a side view illustrating a method of manufacturing a display device, according to an embodiment;

FIG. 15G is a side view illustrating a method of manufacturing a display device, according to an embodiment;

FIG. 15H is a side view illustrating a method of manufacturing a display device, according to an embodiment;

FIG. 15I is a side view illustrating a method of manufacturing a display device, according to an embodiment;

FIG. 15J is a side view illustrating a method of manufacturing a display device, according to an embodiment;

FIG. 16A is a side view illustrating some steps of the method of manufacturing the display device, according to an embodiment;

FIG. 16B is a side view illustrating some steps of the method of manufacturing the display device, according to an embodiment;

FIG. 16C is a side view illustrating some steps of the method of manufacturing the display device, according to an embodiment;

FIG. 16D is a side view illustrating some steps of the method of manufacturing the display device, according to an embodiment;

FIG. 17A is a side view illustrating some steps of the method of manufacturing the display device, according to an embodiment;

FIG. 17B is a side view illustrating some steps of the method of manufacturing the display device, according to an embodiment;

FIG. 17C is a side view illustrating some steps of the method of manufacturing the display device, according to an embodiment;

FIG. 18A is a side view illustrating some steps of the method of manufacturing the display device, according to an embodiment;

FIG. 18B is a side view illustrating some steps of the method of manufacturing the display device, according to an embodiment;

FIG. 18C is a side view illustrating some steps of the method of manufacturing the display device, according to an embodiment;

FIG. 19A is a side view illustrating the method of manufacturing the display device, according to an embodiment;

FIG. 19B is a side view illustrating the method of manufacturing the display device, according to an embodiment;

FIG. 19C is a side view illustrating the method of manufacturing the display device, according to an embodiment;

FIG. 19D is a side view illustrating the method of manufacturing the display device, according to an embodiment;

FIG. 19E is a side view illustrating the method of manufacturing the display device, according to an embodiment;

FIG. 19F is a side view illustrating the method of manufacturing the display device, according to an embodiment;

FIG. 19G is a side view illustrating the method of manufacturing the display device, according to an embodiment;

FIG. 19H is a side view illustrating the method of manufacturing the display device, according to an embodiment;

FIG. 19I is a side view illustrating the method of manufacturing the display device, according to an embodiment;

FIG. 19J is a side view illustrating the method of manufacturing the display device, according to an embodiment;

FIG. 20A is a side view illustrating some steps of the method of manufacturing the display device, according to an embodiment;

FIG. 20B is a side view illustrating some steps of the method of manufacturing the display device, according to an embodiment;

FIG. 20C is a side view illustrating some steps of the method of manufacturing the display device, according to an embodiment; and

FIG. 20D is a side view illustrating some steps of the method of manufacturing the display device, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element (or region, layer, portion, etc.) is referred to as being related to another such as being “on”, “connected to”, or “coupled to” another element, it can be directly on, connected, or coupled to the other element, or intervening elements may be present. As such, as used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

Like reference numerals refer to like elements throughout. In addition, in the drawings, the thicknesses, ratios, and dimensions of elements are exaggerated for effective description of the technical contents. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. For example, a first element could be termed a second element without departing from the scope of the present invention. Similarly, the second element may also be referred to as the first element. The terms of a singular form include plural forms unless otherwise specified.

In addition, terms, such as “below”, “lower”, “above”, “upper”, and the like, are used herein for ease of description to describe one element's relation to another element(s) as illustrated in the figures. The above terms are relative concepts and are described based on the directions indicated in the drawings.

It will be understood that the terms “comprise”, “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

It should be understood that the terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the drawings.

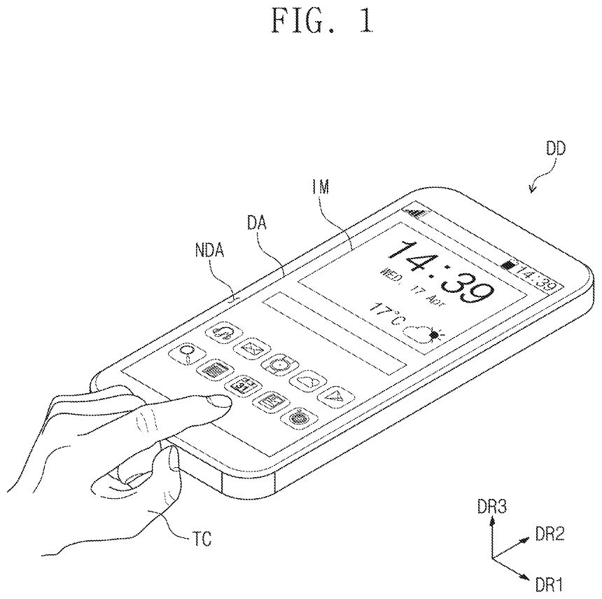

FIG. 1 is a perspective view of a display device DD according to an embodiment.

Referring to FIG. 1, a portable terminal is illustrated as an example of a display device DD according to an embodiment. The portable terminal may include a tablet PC, a smart phone, a personal digital assistant (PDA), a portable multimedia player (PMP), a game machine, a wrist watch-type electronic device, and the like. However, the invention is not limited thereto.

In an embodiment, the display device may be used not only for a large-sized electronic device such as a television or an external billboard, but also for a small and medium-sized electronic device such as a personal computer, a notebook computer, a car navigation unit, and/or a camera.

In an embodiment, the display device DD may be flexible. The expression “being flexible” means a property of being bendable, and a flexible structure may include everything from a completely foldable structure to a structure that can be bent to the level of several nanometers. For example, a flexible display device DD may include a curved display device, a foldable display device, a slidable display device, and/or a rollable display device. Without being limited thereto, however, the display device DD may be rigid.

In an embodiment and as illustrated in FIG. 1, a display surface on which an image IM is displayed is parallel to a plane defined by a first direction DR1 and a second direction DR2. The display device DD includes a plurality of regions divided on the display surface. The display surface includes a display region DA on which an image IM is displayed and a non-display region NDA disposed adjacent to the display region DA. The non-display region NDA may be referred to as a bezel region. As an example, the display region DA may have a tetragonal shape. The non-display region NDA surrounds the display region DA. In addition, although not illustrated, as an example, the display device DD may include a partially curved shape. As a result, one region of the display region DA may have a curved shape.

In an embodiment, the front surface (or upper surface) and the rear surface (or lower surface) of each member constituting the display device DD may be opposed to each other in a third direction DR3, and a normal direction of each of the front and rear surfaces is substantially parallel to the third direction DR3. A separation space between the front surface and the rear surface defined along the third direction DR3 may correspond to the thickness of a member (or unit). In this specification, the expression “in a plan view” may be defined as a state viewed from the third direction DR3. In this specification, the expression “on a cross section” may be defined as a state viewed from the first direction DR1 or the second direction DR2. Meanwhile, directions indicated by the first to third directions DR1, DR2, and DR3, respectively, are relative concepts and may be converted into other directions. In this specification, the expression “overlapping” may mean overlapping in a plan view unless otherwise particularly defined.

In an embodiment, the front surface (or upper surface, or first surface) and rear surface (or lower surface, or second surface) of each member are defined based on a direction in which an image IM is displayed. However, the directions indicated by the first to third directions DR1, DR3, and DR3, respectively, are relative concepts and may be converted into other directions. Hereinafter, the first to third directions refer to the same reference numerals as directions indicated by the first to third directions DR1, DR2, and DR3, respectively.

The display device DD according to an embodiment may sense a user's touch input TC applied from the outside. The user's touch input TC includes various types of external inputs, such as a part of the user's body, light, heat, and/or pressure. In this embodiment, the user's input TC is described as the user's hand applied to the front surface, but this is exemplary and as described above, the user's input TC may be provided in various forms. In addition, the display device DD may sense a user's input applied to a side surface and/or rear surface of the display device DD according to the structure of the display device DD, and the invention is not limited to any one embodiment.

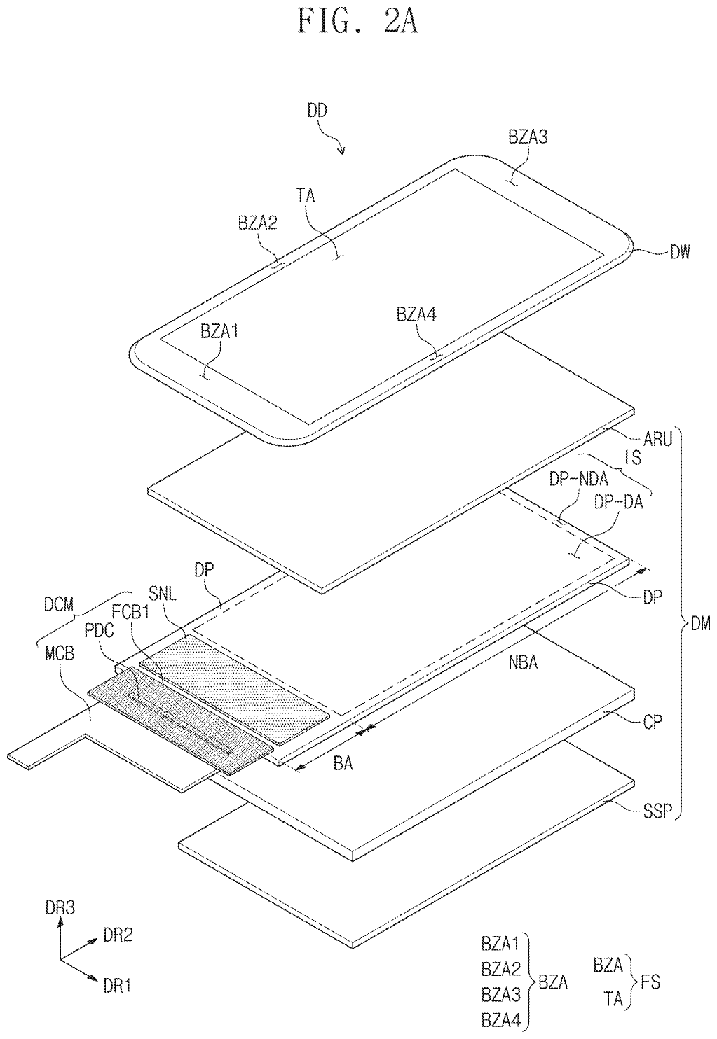

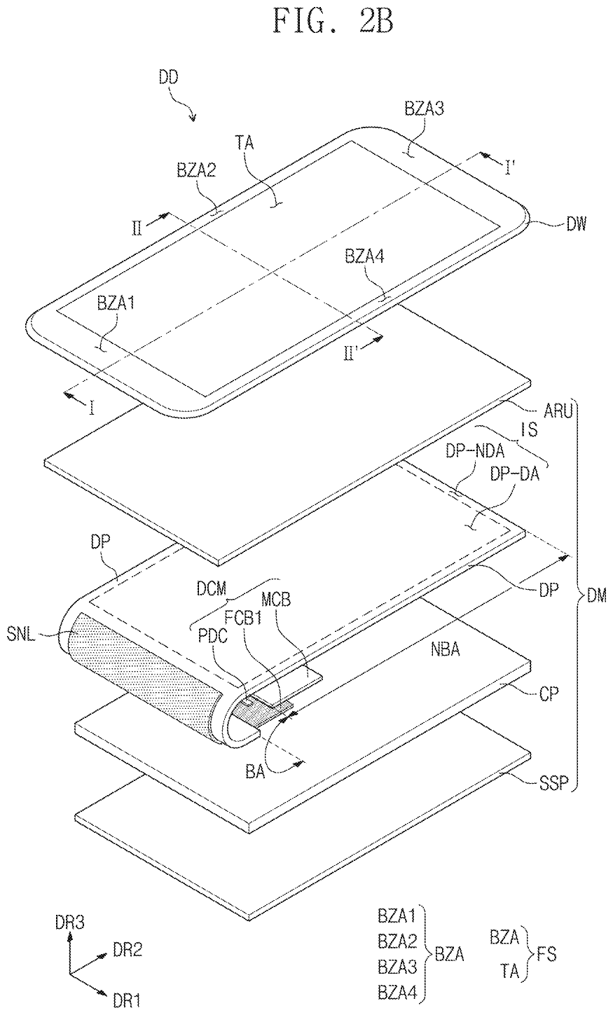

FIGS. 2A and 2B are exploded perspective views of the display device according to an embodiment. More specifically, FIG. 2A is an exploded perspective view of the display device DD in which a bending region BA is not bent, and FIG. 2B is an exploded perspective view of the display device DD in which the bending region BA is bent.

In an embodiment and referring to FIGS. 2A and 2B, the display device DD may include a coating window DW and a display module DM. The coating window DW may be disposed directly on an optical unit ARU. Here, the expression “being directly disposed” may mean being disposed without a separate adhesive or an adhesive layer.

In an embodiment, the coating window DW may provide a front surface FS of the display device DD. The front surface FS of the coating window DW may include a transmission region TA and a bezel region BZA. The transmission region TA of the coating window DW may be an optically transparent region. The coating window DW may transmit an image IM (See FIG. 1) provided by a display panel DP through the transmission region TA, and a user may view the corresponding image IM (see FIG. 1).

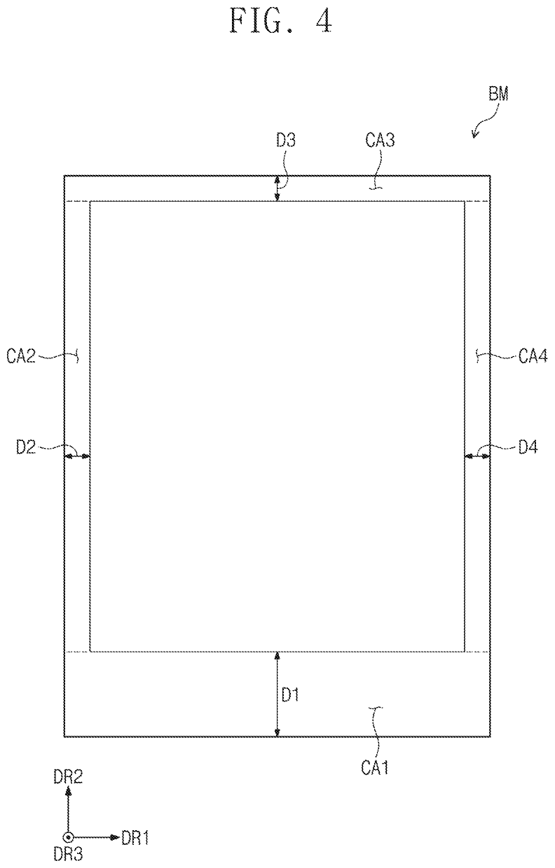

In an embodiment, the bezel region BZA of the coating window DW may overlap a light blocking pattern BM (see FIG. 4) to be described later. The light blocking pattern BM may be a rigid substrate containing a material having a predetermined color. The bezel region BZA of the coating window DW may prevent a configuration of the display panel DP disposed to overlap the light blocking pattern BM (see FIG. 4) from being visually recognized from the outside.

In an embodiment, the bezel region BZA may be adjacent to the transmission region TA. The shape of the transmission region TA may be substantially defined by the bezel region BZA. For example, the bezel region BZA may be disposed outside the transmission region TA to surround the transmission region TA. However, this is illustrated as an example, and the bezel region BZA may be adjacent to only one side of the transmission region TA or may be omitted. In addition, the bezel region BZA may be disposed on a side surface of the display device DD instead of the front surface thereof.

In an embodiment, the bezel region BZA may include a first bezel region BZA1, a second bezel region BZA2, a third bezel region BZA3, and a fourth bezel region BZA4. The first bezel region BZA1 may be disposed below the transmission region TA in a plan view. The second bezel region BZA2 may be disposed on the left side of the transmission region TA in a plan view. The third bezel region BZA3 may be disposed above the transmission region TA in a plan view. The fourth bezel region BZA4 may be disposed on the right side of the transmission region TA in a plan view. The first bezel region BZA1 may face the third bezel region BZA3 in the second direction DR2. The second bezel region BZA2 may face the fourth bezel region BZA4 in the first direction DR1.

In an embodiment, the first bezel region BZA1 may correspond to a first light blocking pattern CA1 (see FIG. 4). The second bezel region BZA2 may correspond to a second light blocking pattern CA2 (see FIG. 4). The third bezel region BZA3 may correspond to a third light blocking pattern CA3 (see FIG. 4). The fourth bezel region BZA4 may correspond to a fourth light blocking pattern CA4 (see FIG. 4).

In an embodiment, the coating window DW may contain an optically transparent insulating material. The coating window DW may contain a resin material. The coating window DW may have a single-layered or multi-layered structure. Since a lamination process is omitted in the display device DD including the coating window DW, the process of manufacturing the display device DD may be simplified and the costs thereof may be reduced.

In an embodiment, the coating window DW may include a functional coating layer such as an anti-fingerprint layer, an anti-reflection layer, and/or a hard coating layer. In an embodiment, the coating window DW is illustrated to have a flat shape in the display region DP-DA, but the shape of the coating window DW may be modified. The edges of the coating window DW, which face each other in the first direction DR1, may provide curved surfaces.

In an embodiment, the display module DM may be disposed on the rear surface of the coating window DW and generate an image. In addition, the display module DM may sense a user's input TC (see FIG. 1).

Although the display module DM is illustrated to provide a flat display surface as an example in an embodiment, the shape of the display module DM may be modified. In an embodiment, the edges of the display module DM, which face each other in the first direction DR1, may be bent from the central portions thereof to provide a curved surface.

In an embodiment, the display module DM may include an optical unit ARU, a display panel DP, a protective panel CP, a support panel SSP, and a driving control module DCM.

In an embodiment, the optical unit ARU may be disposed between the display panel DP and the coating window DW. The optical unit ARU may lower the reflectance of light incident from the outside. The optical unit ARU may include at least one of a retarder, a polarizer, a polarizing film, or a polarizing filter. The optical unit ARU may be attached to the display panel DP by an adhesive layer. However, the type of the optical unit ARU is exemplary and is not limited thereto. For example, the optical unit ARU may include a color filter.

In an embodiment, the display panel DP may be disposed between the coating window DW and the support panel SSP. The display panel DP may display an image in response to an electrical signal. The display panel DP, according to an embodiment, may be a light-emitting display panel, but is not particularly limited thereto. For example, the display panel DP may be an organic light-emitting display panel, an inorganic light-emitting display panel, an organic-inorganic light-emitting display panel, or a quantum dot light-emitting display panel. A light-emitting layer of the organic light-emitting display panel may contain an organic light-emitting material, and a light-emitting layer of the inorganic light-emitting display panel may contain an inorganic light-emitting material. A light-emitting layer of the organic-inorganic light-emitting display panel may contain an organic-inorganic light-emitting material. A light-emitting layer of the quantum dot light-emitting display panel may contain quantum dots and/or quantum rods.

In an embodiment, the display panel DP may include a non-bending region NBA and a bending region BA which extends from an end of the non-bending region NBA and which is bent. The bending region BA may extend from the non-bending region NBA in a direction opposite to the second direction DR2. The bending region BA may be bent to face the rear surface of the non-bending region NBA.

In an embodiment, an image IM (see FIG. 1) provided by the display device DD may be displayed on a front surface IS of the display panel DP. The front surface IS of the display panel DP may include a display region DP-DA and a non-display region DP-NDA. Here, the display region DP-DA may correspond to the display region DA of FIG. 1, and the non-display region DP-NDA may correspond to the non-display region NDA of FIG. 1.

In an embodiment, a bending protective layer SNL may be disposed on the display panel DP and may be bent together with the bending region BA. The bending protective layer SNL may prevent a bent portion of the display panel DP from being damaged by an external impact and/or prevent external foreign substances from entering. The bending protective layer SNL illustrated in the drawing is merely an example, and the shape of the bending protective layer SNL may be changed as needed.

In an embodiment, the bending protective layer SNL may be disposed on the front surface of the display panel DP to protect the bent portion of the display panel DP. The bending protective layer SNL may include a plastic film as a base layer. The bending protective layer SNL may include a plastic film containing any one selected from the group consisting of polyethersulphone (PES), polyacrylate (PAR), polyetherimide (PEI), polyethyelene napthalate (PEN), polyethylene terephthalate (PET), polyphenylene sulfide (PPS), polyallylate, polyimide (PI), polycarbonate (PC), polyaryleneether sulfone, and combinations thereof.

However, in an embodiment, materials constituting the bending protective layer SNL are not limited to plastic resins and may include organic/inorganic composite materials. The bending protective layer SNL may include a porous organic layer and an inorganic material filling the pores of the organic layer. The bending protective layer SNL may have a single-layered or multi-layered structure.

In an embodiment, the display region DP-DA may be activated in response to an electrical signal and display an image. According to an embodiment, the display region DP-DA of the display panel DP may correspond to the transmission region TA of the coating window DW. Meanwhile, in this specification, the expression “a region/portion and a region/portion correspond to each other” means that “they overlap each other”, and the expression is not limited to having a same area and/or a same shape.

In an embodiment, the non-display region DP-NDA may be disposed adjacent to the outside of the display region DP-DA. For example, the non-display region DP-NDA may surround the display region DP-DA. Without being limited thereto, however, the non-display region DP-NDA may be defined in various shapes.

In an embodiment, the non-display region DP-NDA may be a region in which a driving circuit and/or driving line configured to drive elements disposed in the display region DP-DA, various signal lines configured to provide electrical signals, and pads are disposed. The non-display region DP-NDA of the display panel DP may correspond to the bezel region BZA of the coating window DW. The elements of the display panel DP disposed in the non-display region DP-NDA may be prevented from being viewed from the outside by the bezel region BZA.

In an embodiment, the driving control module DCM includes a main circuit board MCB (or driving circuit board), a first circuit board FCB1 (or flexible panel circuit board), and a panel driving circuit PDC. The first circuit board FCB1 may be connected to an end portion of the display panel DP to electrically connect the main circuit board MCB and the display panel DP to each other.

In an embodiment, the first circuit board FCB1 electrically connects the main circuit board MCB and the display panel DP to each other, and the panel driving circuit PDC may be mounted thereon. The panel driving circuit PDC may be mounted by a chip-on-film (COF) method. The panel driving circuit PDC may be implemented as an integrated circuit. Although not separately illustrated, a plurality of passive elements and active elements may be mounted on the main circuit board MCB. The main circuit board MCB may be a rigid circuit board or a flexible circuit board, and the first circuit board FCB1 may be a flexible circuit board. The main circuit board MCB may be positioned on the rear surface of the display panel DP.

In an embodiment, the protective panel CP may be disposed on the rear surface of the display panel DP and protect the display panel DP from an impact. The protective panel CP may include a plastic film as a base layer. The protective panel CP may have a single-layered or multi-layered structure.

In an embodiment, the support panel SSP may be disposed on the rear surface of the protective panel CP and support the display panel DP and the protective panel CP. The support panel SSP may be a metal plate having a rigidity greater than or equal to a standard. The support panel SSP may be a stainless steel plate. The support panel SSP may have a black color to block external light incident on the display panel DP.

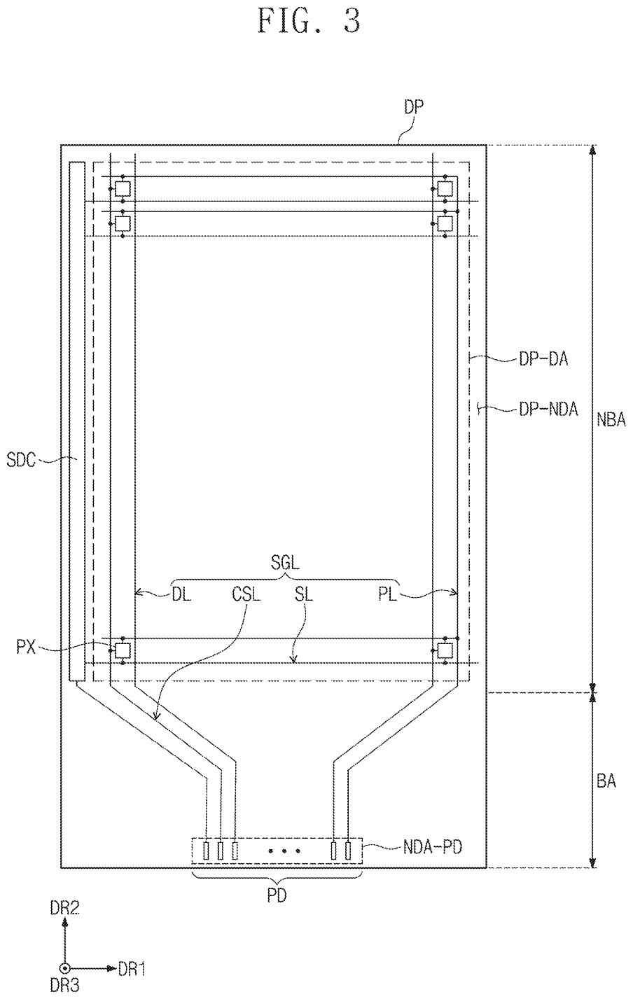

FIG. 3 is a plan view of a display panel DP according to an embodiment.

FIG. 3 illustrates a signal circuit diagram, according to an embodiment. In addition, in FIG. 3, some components are omitted for easy description.

In an embodiment and referring to FIG. 3, the display panel DP may include a display region DP-DA and a non-display region DP-NDA in a plan view. In an embodiment, the non-display region DP-NDA may be defined along an edge of the display region DP-DA. The display region DP-DA and the non-display region DP-NDA of the display panel DP respectively correspond to the display region DA and the non-display region NDA of the display device DD illustrated in FIG. 1.

In an embodiment, the display panel DP may include a non-bending region NBA and a bending region BA that extends from an end of the non-bending region NBA and which is bent. As illustrated in FIG. 3, the non-bending region NBA may be positioned at an upper portion thereof and the bending region BA may be positioned at a lower portion thereof along the second direction DR2. The lower end of the bending region BA may be bent and disposed to face the non-bending region NBA.

In an embodiment, the display panel DP may include a scan driving circuit SDC, a plurality of signal lines SGL (hereinafter referred to as signal lines), a plurality of signal pads PD (hereinafter referred to as signal pads), and a plurality of pixels PX (hereinafter referred to as pixels). The pixels PX are disposed in the display region DP-DA. Each of the pixels PX includes an organic light-emitting diode and a pixel driving circuit connected thereto.

In an embodiment, the scan driving circuit SDC generates a plurality of scan signals (hereinafter referred to as scan signals) and sequentially outputs the scan signals to a plurality of scan lines SL (hereinafter referred to as scan lines). The scan driving circuit SDC may further output another control signal to the driving circuit of the pixels PX.

In an embodiment, the scan driving circuit SDC may include a plurality of thin film transistors formed through the same process as the driving circuit of the pixels PX, for example, a low temperature polycrystaline silicon (LTPS) process or a low temperature polycrystalline oxide (LTPO) process.

In an embodiment, the signal lines SGL include scan lines SL, data lines DL, a power line PL, and a control signal line CSL. The scan lines SL are respectively connected to corresponding pixels PX among the pixels PX, and the data lines DL are respectively connected to corresponding pixels PX among the pixels PX. The power line PL is connected to the pixels PX. The control signal line CSL may provide control signals to the scan driving circuit SDC.

In an embodiment, the signal lines SGL overlap the display region DP-DA and the non-display region DP-NDA. The signal lines SGL may include a pad portion and a line portion. The line portion overlaps the display region DP-DA and the non-display region DP-NDA. The pad portion is connected to the end of the line portion. The pad portion is disposed in the non-display region DP-NDA and overlaps a corresponding signal pad among the signal pads PD. A region in the non-display region DP-NDA, in which the signal pads PD are disposed, may be defined as a pad region NDA-PD.

In an embodiment, the line portion that is substantially connected to the pixel PX constitutes most of the signal lines SGL. The line portion is connected to transistors (not illustrated) of the pixel PX. The line portion may have a single-layered/multi-layered structure, and the line portion may have a single body or may include two or more portions. The two or more portions may be disposed on different layers and connected to each other through a contact hole passing through an insulating layer disposed between the two or more portions.

FIG. 4 is a plan view of a light blocking pattern BM according to an embodiment.

In an embodiment and referring to FIGS. 3 and 4, the light blocking pattern BM may contain a light blocking material so that components disposed below the light blocking pattern BM are not visually recognized from the outside. The light blocking material may be a black resin through which light is not transmitted. The light blocking pattern BM may be disposed to overlap the non-display region DP-NDA of the display panel DP. The light blocking pattern BM may be disposed to overlap the bezel region BZA (see FIG. 2A) of the coating window DW (see FIG. 2A).

In an embodiment, the light blocking pattern BM may include a first light blocking pattern CA1, a second light blocking pattern CA2, a third light blocking pattern CA3, and a fourth light blocking pattern CA4. The first light blocking pattern CA1 may be a region adjacent to the pad region NDA-PD, in which the signal pads PD are disposed, in the non-display region DP-NDA of the display panel DP. The first light blocking pattern CA1 may be disposed adjacent to the lower side of the non-bending region NBA in a plan view. The first light blocking pattern CA1 may be a region corresponding to the first bezel region BZA1 (see FIG. 2A).

In an embodiment, the second light blocking pattern CA2 may extend in the second direction DR2 from the first light blocking pattern CA1 in a plan view. The second light blocking pattern CA2 may be disposed adjacent to the left side of the non-bending region NBA in a plan view. The second light blocking pattern CA2 may be a region corresponding to the second bezel region BZA2 (see FIG. 2A).

In an embodiment, the third light blocking pattern CA3 may extend in the first direction DR1 from the second light blocking pattern CA2. The third light blocking pattern CA3 may face the first light blocking pattern CA1 in a plan view. The third light blocking pattern CA3 may be disposed adjacent to the upper side of the non-bending region NBA in a plan view. The third light blocking pattern CA3 may be a region corresponding to the third bezel region BZA3 (see FIG. 2A). The third light blocking pattern CA3 and the first light blocking pattern CA1 may be spaced apart from each other in the second direction DR2.

In an embodiment, the fourth light blocking pattern CA4 may extend in a direction opposite to the second direction DR2 from the third light blocking pattern CA3. The fourth light blocking pattern CA4 may face the second light blocking pattern CA2 in a plan view. The fourth light blocking pattern CA4 may be disposed adjacent to the right side of the non-bending region NBA in a plan view. The fourth light blocking pattern CA4 may be a region corresponding to the fourth bezel region BZA4 (see FIG. 2A). The fourth light blocking pattern CA4 and the second light blocking pattern CA2 may be spaced apart from each other in the first direction DR1.

In an embodiment, widths D2, D3, and D4 of the second, third, and fourth light blocking patterns CA2, CA3, and CA4, respectively, may be smaller than a width D1 of the first light blocking pattern CA1. For example, the width D1 of the first light blocking pattern CA1 may be greater than or equal to about 2 mm, and the widths D2, D3, and D4 of the second, third and fourth light blocking patterns CA2, CA3 and CA4, respectively, may be about 1.5 mm.

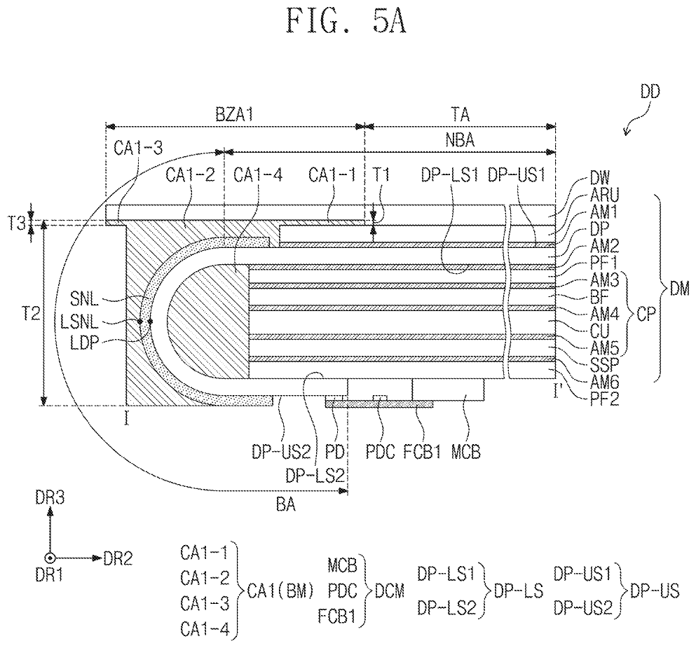

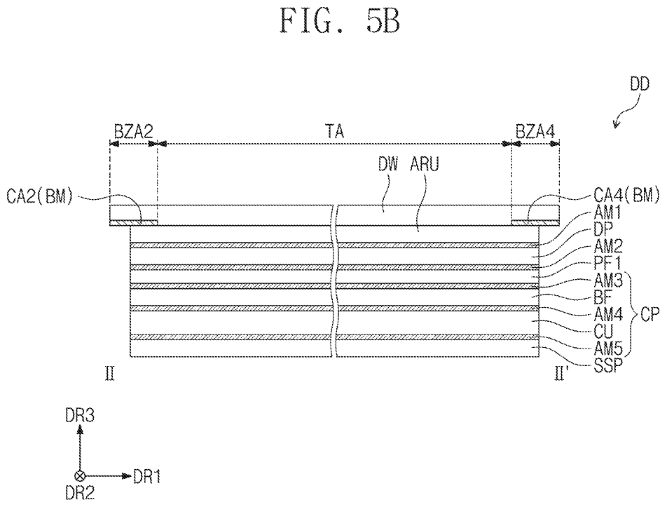

FIG. 5A is a side view of the display device DD according to an embodiment. More specifically, FIG. 5A is a cross-sectional view taken along line I-I′ illustrated in FIG. 2B.

In an embodiment, although the display panel DP is expressed as a single layer in FIG. 5A, the display panel DP may have a multi-layered structure. The display panel DP may include a base layer, a circuit layer, a light-emitting element layer, and an encapsulation layer. In addition, those skilled in the art related to this embodiment may understand that other general-purpose components may be further included in the display panel DP.

In an embodiment, referring to FIG. 5A, the stacked structure of the display device DD may be seen. The display device DD may include a display module DM and a coating window DW disposed on the display module DM. The display module DM may include a display panel DP, an optical unit ARU, a first protective layer PF1, a second protective layer PF2, a protective panel CP, a support panel SSP, and first to six adhesive layers AM1 to AM6, respectively.

In an embodiment, the first to sixth adhesive layers AM1 to AM6, respectively, described below may include a pressure sensitive adhesive film PSA, an optically clear adhesive film (OCA), or an optically clear adhesive resin OCR. The first adhesive layer AM1 to the sixth adhesive layer AM6 contain a photocurable adhesive material or a heat-curable adhesive material, and the material thereof is not particularly limited thereto. Some of the first to sixth adhesive layers AM1 to AM6, respectively, may be omitted.

In an embodiment, an end of the bending region BA of the display panel DP may be bent and disposed on the lower surface of the second protective layer PF2. The end of the bending region BA may face the non-bending region NBA in the third direction DR3. A first upper surface DP-US1 of the display panel DP may be closer to the coating window DW than a first lower surface DP-LS1 thereof. A second upper surface DP-US2 of the display panel DP may be farther away from the coating window DW than a second lower surface DP-LS2 thereof.

In an embodiment, the optical unit ARU may be disposed on an upper surface DP-US of the display panel DP. The optical unit ARU may be disposed between the display panel DP and the coating window DW and overlap the non-bending region NBA. According to an embodiment, the optical unit ARU may not overlap the bending region BA. The optical unit ARU may be bonded on the display panel DP by the first adhesive layer AM1. However, the first adhesive layer AM1 may be omitted if necessary.

In an embodiment, the bending protective layer SNL may be disposed on the upper surface DP-US of the display panel DP and bent together with the bending region BA. The bending protective layer SNL may overlap the bending region BA. A portion of the bending protective layer SNL may partially overlap the non-bending region NBA of the display panel DP.

In an embodiment, the driving control module DCM may be coupled to an end of the display panel DP. The driving control module DCM may include a first circuit board FCB1, a panel driving circuit PDC, and a main circuit board MCB. The first circuit board FCB1 electrically connects the main circuit board MCB and the display panel DP to each other, and the panel driving circuit PDC may be mounted thereon. In an embodiment, the panel driving circuit PDC is illustrated as being mounted on the first circuit board FCB1, but the position of the panel driving circuit PDC may not be limited thereto. For example, the panel driving circuit PDC may be disposed directly on the upper surface DP-US of the display panel DP.

In an embodiment, the first circuit board FCB1 may be electrically connected to the signal pads PD. Here, the signal pads PD may correspond to the signal pads PD disposed in the pad region NDA-PD of FIG. 3.

In an embodiment, the first protective layer PF1 may be disposed on the first lower surface DP-LS1 of the display panel DP to protect the display panel DP from an impact. The first protective layer PF1 may be bonded to the first lower surface DP-LS1 by the second adhesive layer AM2. However, the second adhesive layer AM2 may be omitted if necessary.

In an embodiment, the second protective layer PF2 may be coupled to an end of the display panel DP and the driving control module DCM. The second protective layer PF2 may be disposed on the second lower surface DP-LS2 of the display panel DP. The second protective layer PF2 may be bonded to the support panel SSP by the sixth adhesive layer AM6. However, the sixth adhesive layer AM6 may be omitted if necessary.

In an embodiment, the first light blocking pattern CA1 may overlap the bending region BA in a plan view. The first light blocking pattern CA1 may come in contact with the side surfaces of the first protective layer PF1, the second protective layer PF2, and the protective panel CP. The first light blocking pattern CA1 may come in contact with the bending region BA of the display panel DP. The first light blocking pattern CA1 may come in contact with the bending protective layer SNL. Since the first light blocking pattern CA1 overlaps the bending region BA and the bending protective layer SNL, it is possible to prevent the bending region BA and the bending protective layer SNL from being viewed from the outside.

In an embodiment, the first light blocking pattern CA1 may fill a space between the coating window DW and the display panel DP which are spaced part from each other. The first light blocking pattern CA1 may fill a space between the side surfaces of the display panel DP, the first protective layer PF1, the second protective layer PF2, and the protective panel CP, which are spaced apart from each other. The first light blocking pattern CA1 may cover the bent portion of the bending region BA. The outermost surface of the first light blocking pattern CA1 may protrude more outward than the most outwardly protruding portion LDP of the bending region BA on a cross section. The outermost surface of the first light blocking pattern CA1 may protrude more outward than the most outwardly protruding portion LSNL of the bending protective layer SNL on a cross section.

In an embodiment, the first light blocking pattern CA1 may include a (1-1)-th light blocking pattern CA1-1, a (1-2)-th light blocking pattern CA1-2, a (1-3)-th light blocking pattern CA1-3, and a (1-4)-th light blocking pattern CA1-4. The first light blocking pattern CA1 may correspond to the first bezel region BZA1. In an embodiment, the (1-1)-th to (1-4)-th light blocking patterns CA1-1 to CA1-4, respectively, are described with separate reference numerals, but the (1-1)-th to (1-4)-th light blocking patterns CA1-1 to CA1-4, respectively, may be one member formed by a single process and containing a same material.

In an embodiment, the (1-1)-th light blocking pattern CA1-1 may be disposed directly on the optical unit ARU. The (1-1)-th light blocking pattern CA1-1 may overlap the non-bending region NBA. The (1-1)-th light blocking pattern CA1-1 may have a thin plate shape having a first thickness T1. The (1-1)-th light blocking pattern CA1-1 may be disposed between the optical unit ARU and the coating window DW. The coating window DW may be disposed directly on the upper surface of the (1-1)-th light blocking pattern CA1-1.

In an embodiment, the (1-2)-th light blocking pattern CA1-2 may extend from the (1-1)-th light blocking pattern CA1-1 in a direction opposite to the second direction DR2. The (1-2)-th light blocking pattern CA1-2 may be disposed on the bending region BA and may be disposed adjacent to the outside of the bending region BA. The (1-2)-th light blocking pattern CA1-2 may fill a space between the bending region BA and the coating window DW. The coating window DW may be disposed directly on the upper surface of the (1-2)-th light blocking pattern CA1-2.

In an embodiment, the (1-2)-th light blocking pattern CA1-2 may cover the bending region BA. The upper surface of the (1-2)-th light blocking pattern CA1-2 may come in contact with the coating window DW. The (1-2)-th light blocking pattern CA1-2 may come in contact with the bending protective layer SNL. A second thickness T2 of the (1-2)-th light blocking pattern CA1-2 may be greater than the sum of the first thickness T1 of the (1-2)-th light blocking pattern CA1-1 and the thickness of the display module DM. The outermost surface of the (1-2)-th light blocking pattern CA1-2 may be disposed between the outermost surface of the coating window DW and the most outwardly protruding portion LDP of the bending region BA in the second direction DR2.

In an embodiment, the (1-3)-th light blocking pattern CA1-3 may protrude from the (1-2)-th light blocking pattern CA1-2 in a direction opposite to the second direction DR2. A side surface of the (1-3)-th light blocking pattern CA1-3 may be aligned with a side surface of the coating window DW on a cross section. A third thickness T3 of the (1-3)-th light blocking pattern CA1-3 may be the same as the first thickness T1 of the (1-1)-th light blocking pattern CA1-1. The coating window DW may be disposed directly on the upper surface of the (1-3)-th light blocking pattern CA1-3.

In an embodiment, the (1-4)-th light blocking pattern CA1-4 may be disposed between the bending region BA and the side surfaces of the first protective layer PF1, the second protective layer PF2, and the protective panel CP. The (1-4)-th light blocking pattern CA1-4 may fill a space between the first protective layer PF1 and the bending region BA of the display panel DP, which are spaced apart from each other. The (1-4)-th light blocking pattern CA1-4 may overlap the bending region BA. The (1-4)-th light blocking pattern CA1-4 may come in contact with the lower surface DP-LS of the display panel DP. The (1-4)-th light blocking pattern CA1-4 may come in contact with the side surfaces of the bending region BA, the first protective layer PF1, the second protective layer PF2, and the protective panel CP.

In an embodiment, when the coating window DW is formed by coating and then curing a resin material such as resin, it may be impossible to separately couple the light blocking pattern BM to the rear surface of the coating window DW. When the first light blocking pattern CA1 is formed as illustrated in FIG. 5A, the first light blocking pattern CA1 may cover up to the bending region BA although the first light blocking pattern CA1 is not coupled to the rear surface of the coating window DW. Accordingly, the bending region BA and the bending protective layer SNL may not be visually recognized from the outside due to the first light blocking pattern CA1.

In an embodiment, the coating window DW may be disposed directly on the optical unit ARU and the light blocking pattern BM. The coating window DW may be formed by applying and then curing a resin material such as resin. A step difference corresponding to the light blocking pattern BM may be defined on the lower surface of the coating window DW. The upper surface of the coating window DW may be flat despite the lower surface thereof having a step difference. An outer side surface of the coating window DW may be aligned with an outer side surface of the (1-3)-th light blocking pattern CA1-3.

In an embodiment, the protective panel CP may be disposed on the lower surface DP-LS of the display panel DP. The protective panel CP may protect the display panel DP from an impact transmitted from the lower portion thereof.

In an embodiment, the protective panel CP may include a third adhesive layer AM3, a barrier layer BF, a fourth adhesive layer AM4, a cushion layer CU, and a fifth adhesive layer AM5. The barrier layer BF may be bonded to the lower surface of the first protective layer PF1 by the third adhesive layer AM3. As the barrier layer BF has a color with low light transmittance, it is possible to prevent components below the barrier layer BF from being visually recognized.

In an embodiment, the barrier layer BF may include a flexible synthetic resin film. For example, the barrier layer BF may be a film containing polyimide (PI), polyethylene terephthalate (PET), and the like. However, the material of the barrier layer BF is not limited thereto and the barrier layer BF may contain various materials as needed.

In an embodiment, the cushion layer CU may be bonded to the lower surface of the barrier layer BF by the fourth adhesive layer AM4. The cushion layer CU may absorb an impact transmitted from the lower portion of the display panel DP. The cushion layer CU may be made of a highly elastic material such as a foam sheet having a plurality of openings.

In an embodiment, the support panel SSP may be disposed below the protective panel CP to support the display panel DP and the protective panel CP. The support panel SSP may be a metal plate having a rigidity greater than or equal to a predetermined standard. For example, the support panel SSP may be a stainless steel plate. The support panel SSP may have a black color to block external light incident on the display panel DP.

FIG. 5B is a side view of the display device DD according to an embodiment. More specifically, FIG. 5B is a cross-sectional view taken along line II-II′ of FIG. 2B.

In an embodiment and referring to FIG. 5B, the display device DD may include a support panel SSP, a protective panel CP, a first protective layer PF1, a display panel DP, an optical unit ARU, a light blocking pattern BM, and a coating window DW, which are stacked in the order named. Since FIG. 5B is not adjacent to the bending region BA unlike FIG. 5A, the driving control module DCM, the second protective layer PF2, and the bending region BA may not be present. The same reference numerals will be used for the same components as those in FIG. 5A and the descriptions thereof will be omitted.

In an embodiment, the second bezel region BZA2 and the fourth bezel region BZA4 may be respectively disposed adjacent to both sides of the transmission region TA. The second bezel region BZA2 may correspond to the second light blocking pattern CA2 and the fourth bezel region BZA4 may correspond to the fourth light blocking pattern CA4. The outermost surface of the second bezel region BZA2 on a cross section may protrude more outward than the outer side surface of the first protective layer PF1, the outer side surface of the protective panel CP, and the outer side surface of the support panel SSP. The outermost surface of the fourth bezel region BZA4 on a cross section may protrude more outward than the outer side surface of the first protective layer PF1, the outer side surface of the protective panel CP, and the outer side surface of the support panel SSP. Accordingly, it is possible to prevent a structure below the light blocking pattern BM in the second bezel region BZA2 and the fourth bezel region BZA4 from being visually recognized from the outside.

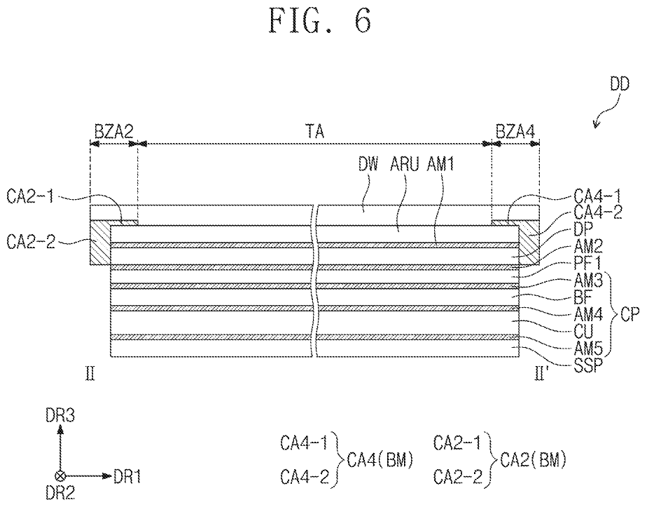

FIG. 6 is a side view of the display device DD according to an embodiment.

In an embodiment and referring to FIG. 6, except for the second light blocking pattern CA2 and the fourth light blocking pattern CA4, the display device DD described in FIG. 6 is the same as the display device DD described in FIG. 5B. The same reference numerals will be used for the same components, and the descriptions thereof will be omitted.

In an embodiment, the second light blocking pattern CA2 may include a (2-1)-th light blocking pattern CA2-1 extending in the first direction DR1 and a (2-2)-th light blocking pattern CA2-2 extending in the third direction DR3. The (2-1)-th light blocking pattern CA2-1 may have the same shape as the second light blocking pattern CA2 described with reference to FIG. 5B. The (2-2)-th light blocking pattern CA2-2 may cover one side surface of the optical unit ARU and one side surface of the display panel DP on a cross section.

In an embodiment, the fourth light blocking pattern CA4 may include a (4-1)-th light blocking pattern CA4-1 extending in the first direction DR1 and a (4-2)-th light blocking pattern CA4-2 extending in the third direction DR3. The (4-1)-th light blocking pattern CA4-1 may have the same shape as the fourth light blocking pattern CA4 described with reference to FIG. 5B. The (4-2)-th light blocking pattern CA4-2 may cover the other side surface of the optical unit ARU and the other side surface of the display panel DP on a cross section.

In an embodiment, as the (2-2)-th light blocking pattern CA2-2 and the (4-2)-th light blocking pattern CA4-2 cover the side surfaces of the display panel DP, they may serve as a protective layer configured to protect the side surfaces of the display panel DP from an external impact.

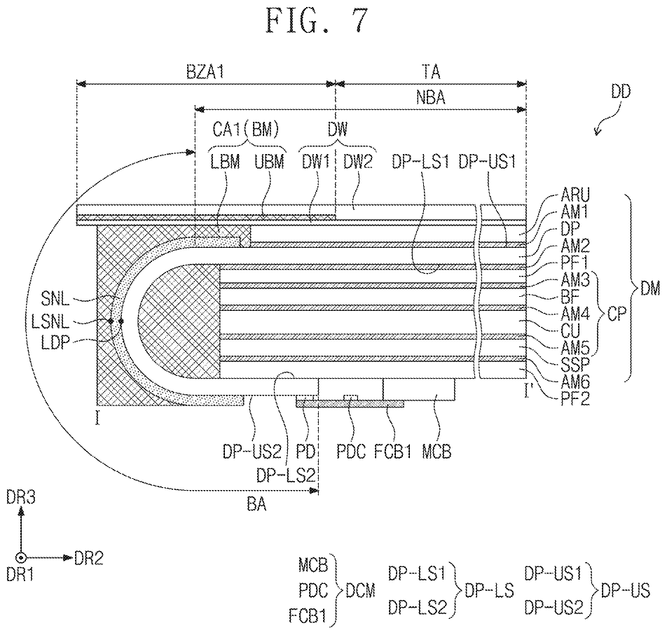

FIG. 7 is a side view of the display device DD according to an embodiment.

In an embodiment and referring to FIG. 7, since the display device DD illustrated in FIG. 7 is the same as the display device DD described with reference to FIG. 5A except for the light blocking pattern BM and the coating window DW, the descriptions of the same components will be omitted.

In an embodiment, the first light blocking pattern CA1 may include a lower light blocking pattern LBM and an upper light blocking pattern UBM. The lower light blocking pattern LBM may come in contact with the side surfaces of the bending region BA, the first protective layer PF1, the second protective layer PF2, and the protective panel CP. The lower light blocking pattern LBM may fill a space between the bending region BA and the side surfaces of the first and second protective layers PF1 and PF2 and the protective panel CP. The lower light blocking pattern LBM may cover the bending region BA and the bending protective layer SNL. The lower light blocking pattern LBM may come in contact with the bending protective layer SNL. The lower light blocking pattern LBM may have a flat upper surface. The upper surface of the lower light blocking pattern LBM may be aligned with the upper surface of the optical unit ARU.

In an embodiment, the upper light blocking pattern UBM may be disposed on the lower light blocking pattern LBM and contain a material different from that of the lower light blocking pattern LBM. The upper light blocking pattern UBM may correspond to the first bezel region BZA1. At least one of the upper light blocking pattern UBM or the lower light blocking pattern LBM may contain a material that blocks light so that the bending region BA and the bending protective layer SNL may not be visually recognized from the outside. At least one of the upper light blocking pattern UBM or the lower light blocking pattern LBM may contain a black resin having low light transmittance. For example, the upper light blocking pattern UBM may contain a black resin and the lower light blocking pattern LBM may contain the same material as that of the coating window DW.

In an embodiment, the coating window DW may include a first coating window DW1 and a second coating window DW2. The first coating window DW1 may be directly disposed between the lower light blocking pattern LBM and the upper light blocking pattern UBM. The first coating window DW1 may have a first modulus value smaller than the modulus value of the second coating window DW2. The first coating window DW1 may serve to reduce an external impact.

In an embodiment, the second coating window DW2 may be disposed directly on the upper light blocking pattern UBM and the first coating window DW1. The second coating window DW2 may have a second modulus value greater than the first modulus value. The second coating window DW2 may block an external impact to prevent damage to a stacked structure below the second coating window DW2.

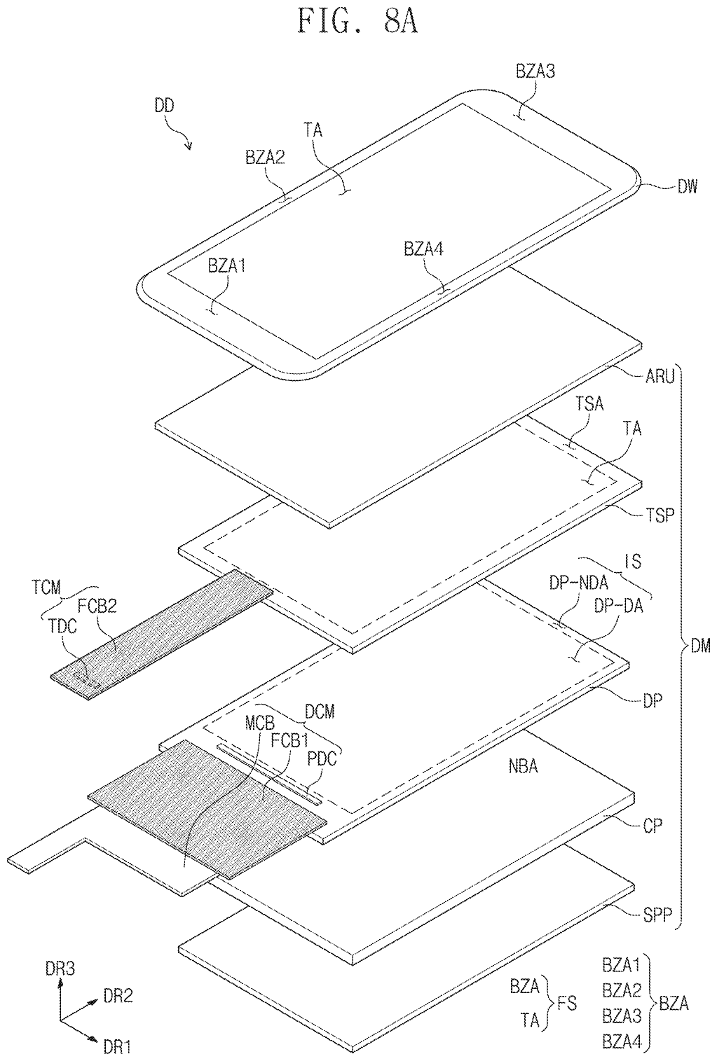

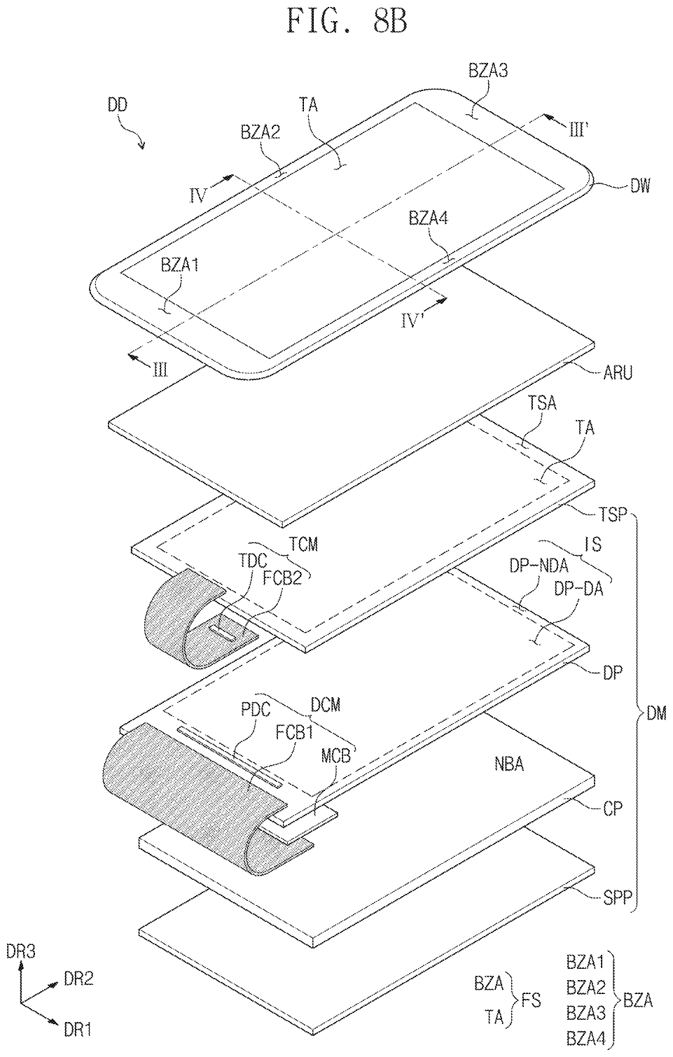

FIGS. 8A and 8B are exploded perspective views of the display device DD according to an embodiment. More specifically, FIG. 8A is an exploded perspective view of the display device DD in which the first circuit board FCB1 and the second circuit board FCB2 are not bent, and FIG. 8B is an exploded perspective view of the display device DD in which the first circuit board FCB1 and the second circuit board FCB2 are bent. Here, the descriptions of the same components as those described in FIGS. 2A and 2B will be omitted.

In an embodiment and referring to FIGS. 8A and 8B, the display module DM may include a display panel DP and a driving control module DCM connected to the display panel DP. The display panel DP may not be bent and may be rigid. The driving control module DCM may include a panel driving circuit PDC, a first circuit board FCB1, and a main circuit board MCB. The panel driving circuit PDC may be disposed on the non-display region DP-NDA of the display panel DP. This may be performed in a chip-on-glass (COG) type panel driving circuit PDC mounting method.

In an embodiment, the first circuit board FCB1 may be disposed on the non-display region DP-NDA of the display panel DP and may be bent. The first circuit board FCB1 may be connected to the end portion of the display panel DP to electrically connect the main circuit board MCB and the display panel DP to each other. The first circuit board FCB1 may be bent so that one end thereof may be positioned on the rear surface of the display panel DP. The end of the first circuit board FCB1 may face the rear surface of the non-display region DP-NDA in the third direction DR3. The main circuit board MCB may be positioned on the rear surface of the display panel DP.

In an embodiment, the display module DM may include a touch sensing panel TSP and a touch control unit TCM. The touch sensing panel TSP may be disposed between the display panel DP and the optical unit ARU and connected to the second circuit board FCB2. The touch sensing panel TSP may obtain the coordinate information of a user's input TC (see FIG. 1). The touch sensing panel TSP may sense various types of inputs provided from the outside of the display device DD. In an embodiment, the touch sensing panel TSP may sense an input by a user's body, but the embodiment is not limited thereto. For example, the touch sensing panel TSP may sense various types of external inputs such as light, heat, and/or pressure. In addition, the touch sensing panel TSP may sense not only an input in contact with a sensing surface, but also an input close to the sensing surface.

In an embodiment, the touch sensing panel TSP may be, for example, a capacitive touch panel, an electromagnetic induction-type touch panel, or the like. The touch sensing panel TSP may include a base layer, sensing electrodes, and signal lines connected to the sensing electrodes.

In an embodiment, the touch control unit TCM may include a second circuit board FCB2 and a touch driving circuit TDC. The second circuit board FCB2 electrically connects the main circuit board MCB and the touch sensing panel TSP to each other, and the touch driving circuit TDC may be mounted thereon. The second circuit board FCB2 may be bent like the first circuit board FCB1. The second circuit board FCB2 may electrically connect the main circuit board MCB and the touch sensing panel TSP to each other. The touch driving circuit TDC may be implemented as an integrated circuit. The second circuit board FCB2 may be a flexible circuit board.

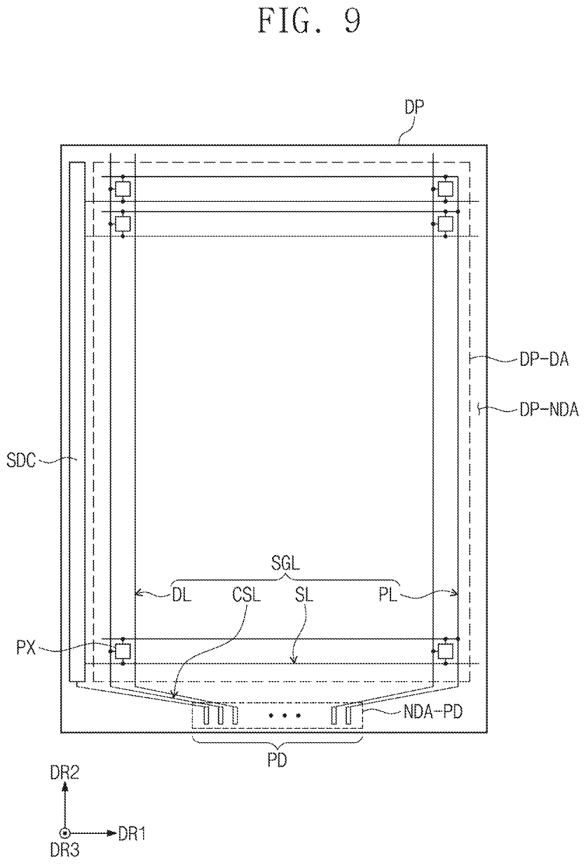

FIG. 9 is a plan view of the display panel DP according to an embodiment. Hereinafter, the descriptions of the same components as those described in FIG. 3 will be omitted.

In an embodiment and referring to FIG. 9, unlike the display panel DP of FIG. 3, the bending region BA (see FIG. 3) may not be separately present in FIG. 9. Therefore, among the non-display region DP-NDA of the display panel DP, a region located below the display region DP-DA in a plan view may not extend long in a direction opposite to the second direction DR2. The pad region NDA-PD in which the signal pads PD are disposed may be disposed below the non-display region DP-NDA.

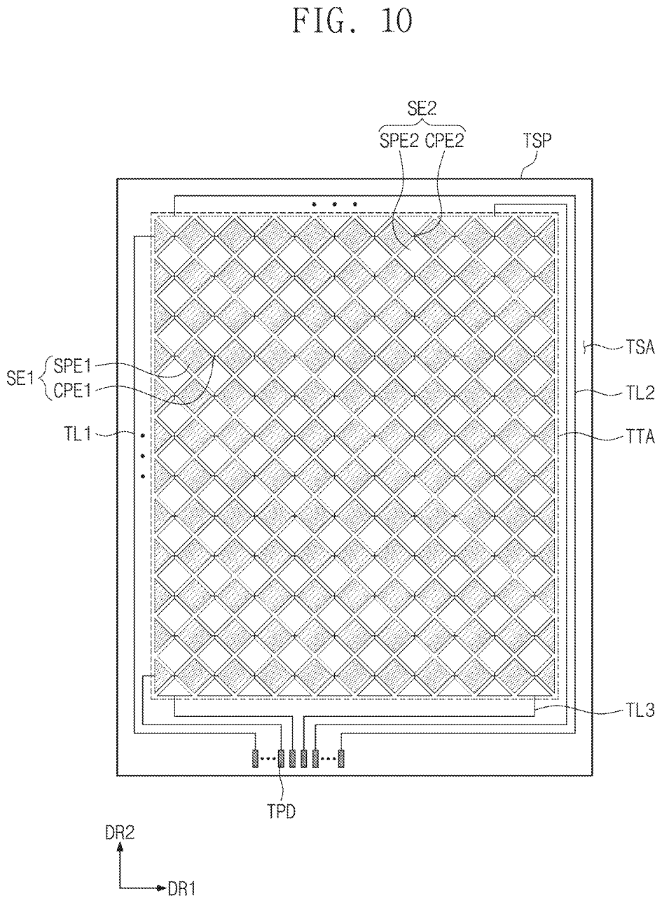

FIG. 10 is a plan view of a touch sensing panel TSP according to an embodiment.

In an embodiment and referring to FIG. 10, the touch sensing panel TSP may sense a touch input TC (see FIG. 1) and obtain information on the location and/or intensity of the external touch input. The touch sensing panel TSP may include a touch region TTA and a touch peripheral region TSA in a plan view. In an embodiment, the touch peripheral region TSA may be defined along the edge of the touch region TTA. The touch region TTA and the touch peripheral region TSA of the touch sensing panel TSP may respectively correspond to the display region DA and the non-display region NDA of the display device DD illustrated in FIG. 1.

In an embodiment, the touch sensing panel TSP includes a plurality of first sensing electrodes SE1, a plurality of second sensing electrodes SE2, a plurality of sensing lines TL1, TL2, and TL3, and a plurality of sensing pads TPD.

In an embodiment, the first sensing electrodes SE1 and the second sensing electrodes SE2 are disposed in the touch region TTA. The touch sensing panel TSP may obtain information on a touch input through a change in capacitance between the first sensing electrodes SE1 and the second sensing electrodes SE2.

In an embodiment, each of the first sensing electrodes SE1 may extend along the first direction DR1 and may be arranged along the second direction DR2. The first sensing electrodes SE1 may include a plurality of first sensing patterns SPE1 and a plurality of first connection patterns CPE1.

In an embodiment, the first sensing patterns SPE1 constituting one first sensing electrode may be spaced apart from each other and arranged along the first direction DR1. In an embodiment, for easy description, the first sensing patterns SPE1 are illustrated by shading. The first connection patterns CPE1 may be disposed between the first sensing patterns SPE1 to connect two adjacent first sensing patterns SPE1 to each other.

In an embodiment, each of the second sensing electrodes SE2 extends along the second direction DR2 and they are arranged along the first direction DR1. The second sensing electrodes SE2 may include a plurality of second sensing patterns SPE2 and a plurality of second connection patterns CPE2.

In an embodiment, the second sensing patterns SPE2 constituting one second sensing electrode are spaced apart from each other and arranged along the second direction DR2. The second connection patterns CPE2 are disposed between the second sensing patterns SPE2 to connect two adjacent second sensing patterns SP1 to each other.

In an embodiment, the sensing lines TL1, TL2, and TL3 are disposed in the touch peripheral region TSA. The sense lines TL1, TL2, and TL3 may include first sense lines TL1, second sense lines TL2, and third sense lines TL3. The first sensing lines TL1 are respectively connected to the first sensing electrodes SE1. The second sensing lines TL2 are respectively connected to one ends of the second sensing electrodes SE2.

In an embodiment, the third sensing lines TL3 may be respectively connected to the other ends of the second sensing electrodes SE2. The other ends of the second sensing electrodes SE2 may be portions opposite to the one ends of the second sensing electrodes SE2. According to an embodiment, the second sensing electrodes SE2 may be connected to the second sensing lines TL2 and the third sensing lines TL3. Accordingly, sensitivity according to a region may be uniformly maintained for the second sensing electrodes SE2 having a relatively longer length than the first sensing electrodes SE1. Meanwhile, this is illustrated as an example, and the third sensing lines TL3 may be omitted and the invention is not limited to any one embodiment.

In an embodiment, the sensing pads TPD are disposed in the touch peripheral region TSA. The sensing pads TPD are respectively connected to the sensing lines TL1, TL2, and TL3 to receive an external signal from the first sensing electrodes SE1 and the second sensing electrodes SE2. The sensing pads TPD may be connected to the second circuit board FCB2 (see FIG. 8B).

FIG. 11 is a plan view of the light blocking pattern BM according to an embodiment. Here, the descriptions of the same components as those described with reference to FIG. 4 will be omitted.

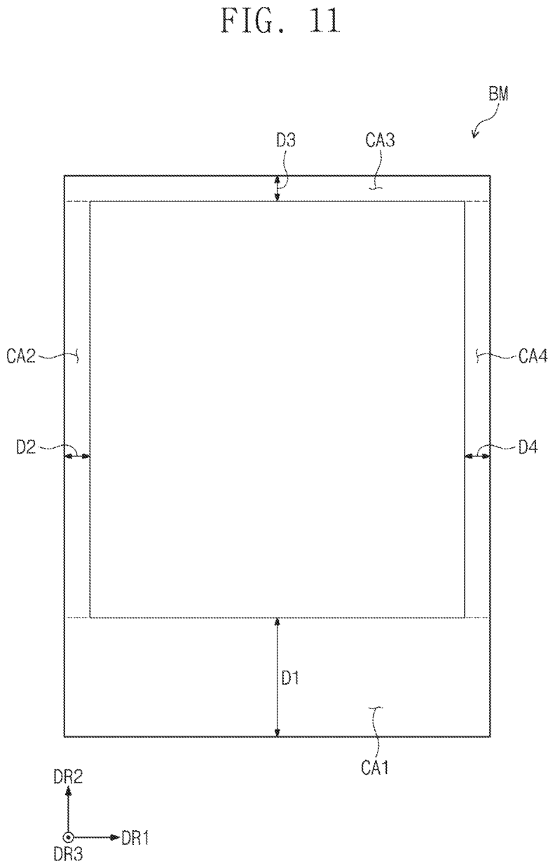

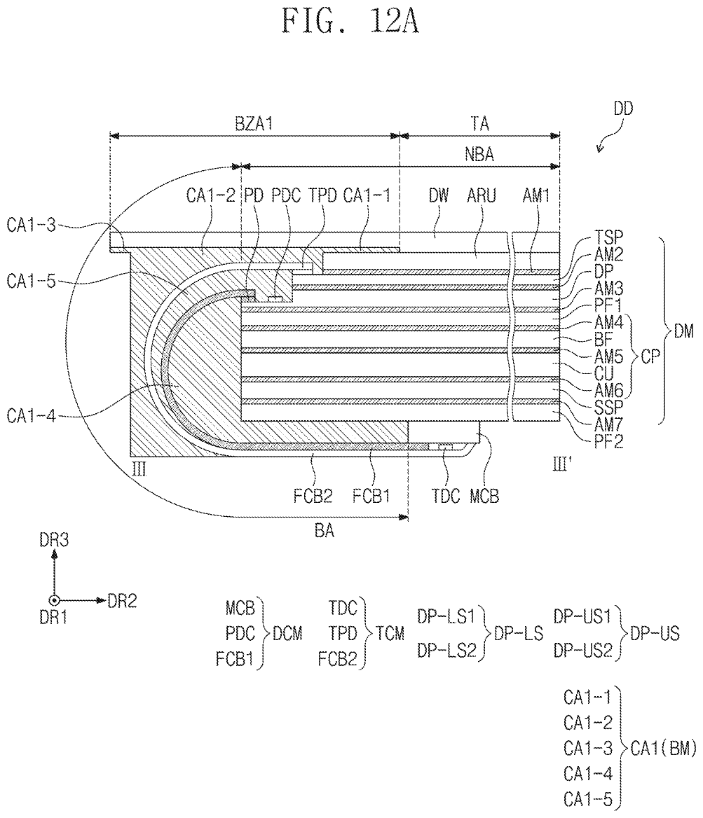

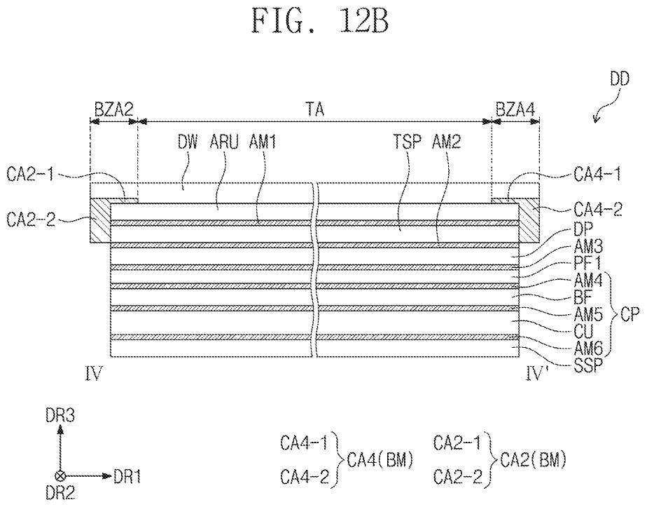

In an embodiment and referring to FIG. 11, the light blocking pattern BM may include a first light blocking pattern CA1, a second light blocking pattern CA2, a third light blocking pattern CA3, and a fourth light blocking pattern CA4. Widths D2, D3, and D4 of the second, third, and fourth light blocking patterns CA2, CA3, and CA4, respectively, may be smaller than the width D1 of the first light blocking pattern CA1. The width D1 of the first light blocking pattern CA1 may be large enough to cover the bent portion of the second circuit board FCB2 of FIG. 12A in a plan view.

FIG. 12A is a side view of the display device according to an embodiment. More specifically, FIG. 12A is a cross-sectional view taken along line III-III′ of FIG. 8B. Hereinafter, the same reference numerals will be used for the same components as those described in FIG. 5A, and the descriptions thereof will be omitted.

In an embodiment and referring to FIG. 12A, the display device DD may include a display panel DP, an optical unit ARU, a first protective layer PF1, a second protective layer PF2, a protective panel CP, a support panel SSP, a touch sensing panel TSP, a coating window DW, and first to seventh adhesive layers AM1 to AM7, respectively. Some of the first to seventh adhesive layers AM1 to AM7, respectively, which will be described below may be omitted.

In an embodiment, a panel driving circuit PDC may be disposed on the display panel DP. However, the position of the panel driving circuit PDC is not limited thereto and the panel driving circuit PDC may be disposed in various positions. For example, the panel driving circuit PDC may be disposed on the first circuit board FCB1.

In an embodiment, the first circuit board FCB1 may be electrically connected to the signal pads PD. Here, the signal pads PD may correspond to the signal pads PD disposed in the pad region NDA-PD of FIG. 9. The first circuit board FCB1 may be bent. One end of the first circuit board FCB1 may be disposed on the front surface of the display panel DP, and the other end of the first circuit board FCB1 may be disposed on the rear surface of the display panel DP. The other end of the first circuit board FCB1 may be connected to the main circuit board MCB.

In an embodiment, the touch sensing panel TSP may be disposed on the display panel DP and sense an input signal. The second adhesive layer AM2 bonded between the touch sensing panel TSP and the display panel DP may be omitted. The touch sensing panel TSP may be disposed between the display panel DP and the optical unit ARU and electrically connected to the second circuit board FCB2.

In an embodiment, the touch control unit TCM may include a touch driving circuit TDC, a second circuit board FCB2, and a touch pad TPD. The touch control unit TCM may be coupled to an end of the touch sensing panel TSP. The touch pad TPD may be disposed on the touch sensing panel TSP. Here, the touch pad TPD may be the same as the touch pad TPD illustrated in FIG. 10.

In an embodiment, the second circuit board FCB2 may be connected to an end portion of the touch sensing panel TSP to electrically connect the main circuit board MCB and the touch sensing panel TSP to each other. The second circuit board FCB2 may transmit an input signal sensed by the touch sensing panel TSP. The second circuit board FCB2 may be bent together with the first circuit board FCB1. One end of the second circuit board FCB2 may be disposed on the front surface of the touch sensing panel TSP, and the other end of the second circuit board FCB2 may be disposed on the rear surface of the touch sensing panel TSP. The other end of the second circuit board FCB2 may be connected to the main circuit board MCB.

In an embodiment, the first light blocking pattern CA1 may overlap the bent portion of the first circuit board FCB1 in a plan view and the bent portion of the second circuit board FCB2 in a plan view. The first light blocking pattern CA1 may come in contact with the side surfaces of the first protective layer PF1, the second protective layer PF2, and the protective panel CP. The first light blocking pattern CA1 may come in contact with the bent portion of the first circuit board FCB1 and the bent portion of the second circuit board FCB2. The first light blocking pattern CA1 may cover the bent portion of the first circuit board FCB1 and the bent portion of the second circuit board FCB2. The first light blocking pattern CA1 may protrude more outward than the most outwardly protruding portion of the bent first circuit board FCB1 and the bent second circuit board FCB2. The first light blocking pattern CA1 may prevent the bent portions of the first circuit board FCB1 and the second circuit board FCB2 from being viewed from the outside.

In an embodiment, the first light blocking pattern CA1 may fill a space between the second circuit board FCB2 and the coating window DW, which are spaced apart from each other. The first light blocking pattern CA1 may fill a space between the first circuit board FCB1 and the second circuit board FCB2, which are spaced apart from each other. The first light blocking pattern CA1 may fill a space between the side surfaces of the first circuit board FCB1, the first protective layer PF1, the second protective layer PF2, and the protective panel CP, which are spaced apart from each other.

In an embodiment, the first light blocking pattern CA1 may include a (1-1)-th light blocking pattern CA1-1, a (1-2)-th light blocking pattern CA1-2, a (1-3)-th light blocking pattern CA1-3, a (1-4)-th light blocking pattern CA1-4, and a (1-5)-th light blocking pattern. The first light blocking pattern CA1 may correspond to the first bezel region BZA1. In an embodiment, the (1-1)-th to (1-5)-th light blocking patterns CA1-1 to CA1-5, respectively, are respectively described with separate reference numerals, but the (1-1)-th to (1-5)-th light blocking patterns CA1-1 to CA1-5, respectively, may be one member formed by a single process and containing a same material.

In an embodiment, the (1-1)-th light blocking pattern CA1-1 may be disposed directly on the optical unit ARU. The (1-1)-th light blocking pattern CA1-1 may be disposed between the optical unit ARU and the coating window DW. The coating window DW may be disposed directly on the upper surface of the (1-1)-th light blocking pattern CA1-1.

In an embodiment, the (1-2)-th light blocking pattern CA1-2 may extend in a direction opposite to the second direction DR2 from the (1-1)-th light blocking pattern CA1-1. The (1-2)-th light blocking pattern CA1-2 may be disposed on the second circuit board FCB2 and may be disposed adjacent to the outside of the second circuit board FCB2. The (1-2)-th light blocking pattern CA1-2 may fill a space between the second circuit board FCB2 and the coating window DW, which are spaced apart from each other. The coating window DW may be disposed directly on the (1-2)-th light blocking pattern CA1-2.

In an embodiment, the (1-2)-th light blocking pattern CA1-2 may cover the first circuit board FCB1 and the second circuit board FCB2. The upper surface of the (1-2)-th light blocking pattern CA1-2 may come in contact with the coating window DW. The (1-2)-th light blocking pattern CA1-2 may come in contact with the second circuit board FCB2. The thickness of the (1-2)-th light blocking pattern CA1-2 may be greater than the sum of the thickness of the (1-1)-th light blocking pattern CA1-1 and the thickness of the display module DM. The outermost surface of the (1-2)-th light blocking pattern CA1-2 may be disposed between the outermost surface of the coating window DW and the most outwardly protruding portion of the second circuit board FCB2 in the second direction DR2.

In an embodiment, the (1-3)-th light blocking pattern CA1-3 may protrude from the (1-2)-th light blocking pattern CA1-2 in a direction opposite to the second direction DR2. The side surface of the (1-3)-th light blocking pattern CA1-3 may be aligned with the side surface of the coating window DW on a cross section. The thickness of the (1-3)-th light blocking pattern CA1-3 may be the same as that of the (1-1)-th light blocking pattern CA1-1. The coating window DW may be disposed directly on the upper surface of the (1-3)-th light blocking pattern CA1-3.

In an embodiment, the (1-4)-th light blocking pattern CA1-4 may be disposed between the first circuit board FCB1 and a side surface of the first protective layer PF1. The (1-4)-th light blocking pattern CA1-4 may be disposed between the bent portion of the first circuit board FCB1 and the side surfaces of the first protective layer PF1, the second protective layer PF2, and the protective panel CP. The (1-4)-th light blocking pattern CA1-4 may fill a space between the bent portion of the first circuit board FCB1 and the first protective layer PF1, which are spaced apart from each other. The (1-4)-th light blocking pattern CA1-4 may overlap the bent portion of the first circuit board FCB1. The (1-4)-th light blocking pattern CA1-4 may come in contact with the rear surface of the first circuit board FCB1 and the side surfaces of the first protective layer PF1, the second protective layer PF2, and the protective panel CP.

In an embodiment, the (1-5)-th light blocking pattern CA1-5 may be disposed between the first circuit board FCB1 and the second circuit board FCB2. The (1-5)-th light blocking pattern CA1-5 may fill a space between the first circuit board FCB1 and the second circuit board FCB2, which are spaced apart from each other. The (1-5)-th light blocking pattern CA1-5 may overlap the bent portion of the second circuit board FCB2. The (1-5)-th light blocking pattern CA1-5 may overlap the bent portion of the first circuit board FCB1. The (1-5)-th light blocking pattern CA1-5 may come in contact with the rear surface of the second circuit board FCB2 and the upper surface of the first circuit board FCB1. The (1-5)-th light blocking pattern CA1-5 may come in contact with a side surface of the display panel DP.

FIG. 12B is a side view of the display device DD according to an embodiment.

In an embodiment and referring to FIG. 12B, the second light blocking pattern CA2 may include a (2-1)-th light blocking pattern CA2-1 extending in the first direction DR1 and a (2-2)-th light blocking pattern CA2-2 extending in the third direction DR3. The (2-2)-th light blocking pattern CA2-2 may cover one side of the optical unit ARU and one side of the touch sensing panel TSP on a cross section.

In an embodiment, the fourth light blocking pattern CA4 may include a (4-1)-th light blocking pattern CA4-1 extending in the first direction DR1 and a (4-2)-th light blocking pattern CA4-2 extending in the third direction DR3. The (4-2)-th light blocking pattern CA4-2 may cover the other side of the optical unit ARU and the other side of the touch sensing panel TSP on a cross section.

As the (2-2)-th light blocking pattern CA2-2 and the (4-2)-th light blocking pattern CA4-2 cover a side surface of the touch sensing panel TSP, they may serve as a protective layer configured to protect the side surface of the touch sensing panel TSP from an external impact.

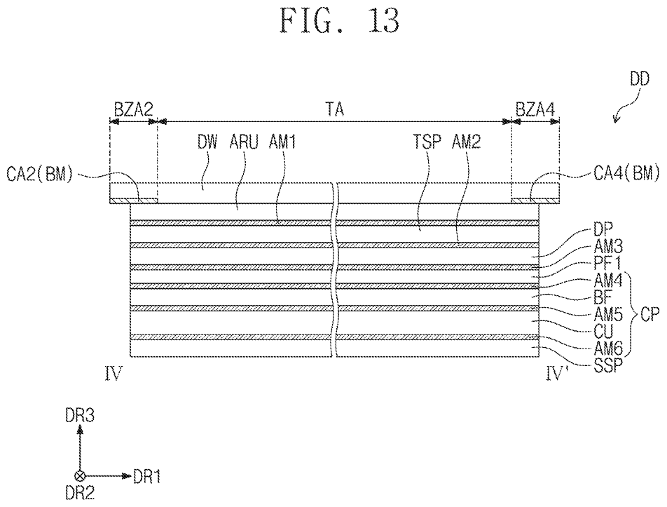

FIG. 13 is a side view of the display device DD according to an embodiment.

In an embodiment and referring to FIG. 13, unlike the second and fourth light blocking patterns CA2 and CA4 described with reference to FIG. 12B, each of the second and fourth light blocking patterns CA2 and CA4 may extend only in the first direction DR1.

FIG. 14 is a side view of the display device DD according to an embodiment.

In an embodiment and referring to FIG. 14, as the display device DD of FIG. 14 is the same as the display device DD described with reference to FIG. 12A except for the light blocking pattern BM and the coating window DW, the descriptions of the same components will be omitted.

In an embodiment, the first light blocking pattern CA1 may include a lower light blocking pattern LBM and an upper light blocking pattern UBM. The lower light blocking pattern LBM may come in contact with the side surfaces of the first and second circuit boards FCB1 and FCB2, respectively, the first and second protective layers PF1 and PF2, respectively, and the protective panel CP. The lower light blocking pattern LBM may fill a space between the side surfaces of the first circuit board FCB1, the first protective layer PF1, the second protective layer PF2, and the protective panel CP. The lower light blocking pattern LBM may fill a space between the first circuit board FCB1 and the second circuit board FCB2, which are spaced apart from each other. The lower light blocking pattern LBM may cover the bent portion of the first circuit board FCB1 and the bent portion of the second circuit board FCB2. The lower light blocking pattern LBM may have a flat upper surface. The upper surface of the lower light blocking pattern LBM may be aligned with the upper surface of the optical unit ARU.

In an embodiment, the upper light blocking pattern UBM may be disposed above the lower light blocking pattern LBM and contain a material different from that of the lower light blocking pattern LBM. The upper light blocking pattern UBM may correspond to the first bezel region BZA1. At least one of the upper light blocking pattern UBM or the lower light blocking pattern LBM may contain a light blocking material so that the bent portion of the first circuit board FCB1 and the bent portion of the second circuit board FCB2 are prevented from being visually recognized. At least one of the upper light blocking pattern UBM or the lower light blocking pattern LBM may contain a black resin having low light transmittance. For example, the upper light blocking pattern UBM may contain a black resin and the lower light blocking pattern LBM may contain the same material as that of the coating window DW.

In an embodiment, the coating window DW may include a first coating window DW1 and a second coating window DW2. The first coating window DW1 may be directly disposed between the lower light blocking pattern LBM and the upper light blocking pattern UBM. The first coating window DW1 may have a first modulus value smaller than the modulus value of the second coating window DW2. The first coating window DW1 may serve to reduce an external impact.

In an embodiment, the second coating window DW2 may be disposed directly on the upper light blocking pattern UBM and the first coating window DW1. The second coating window DW2 may have a second modulus value greater than the first modulus value. The second coating window DW2 may block an external impact to prevent damage to a stacked structure below the second coating window DW2.

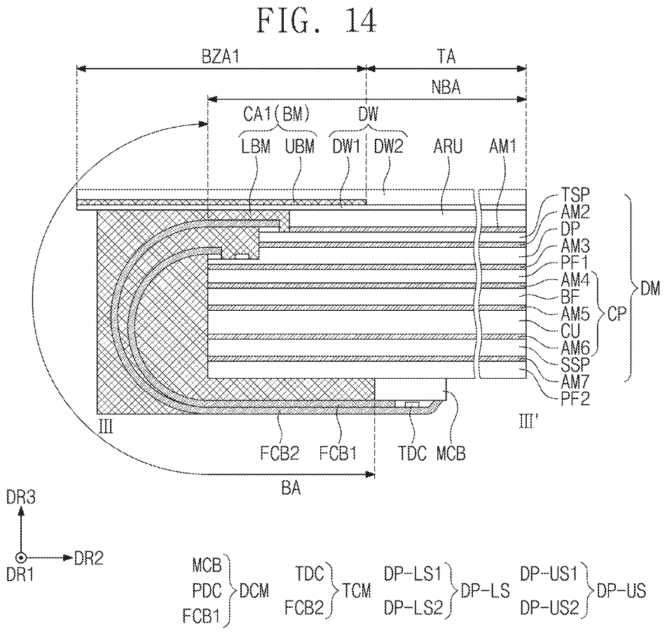

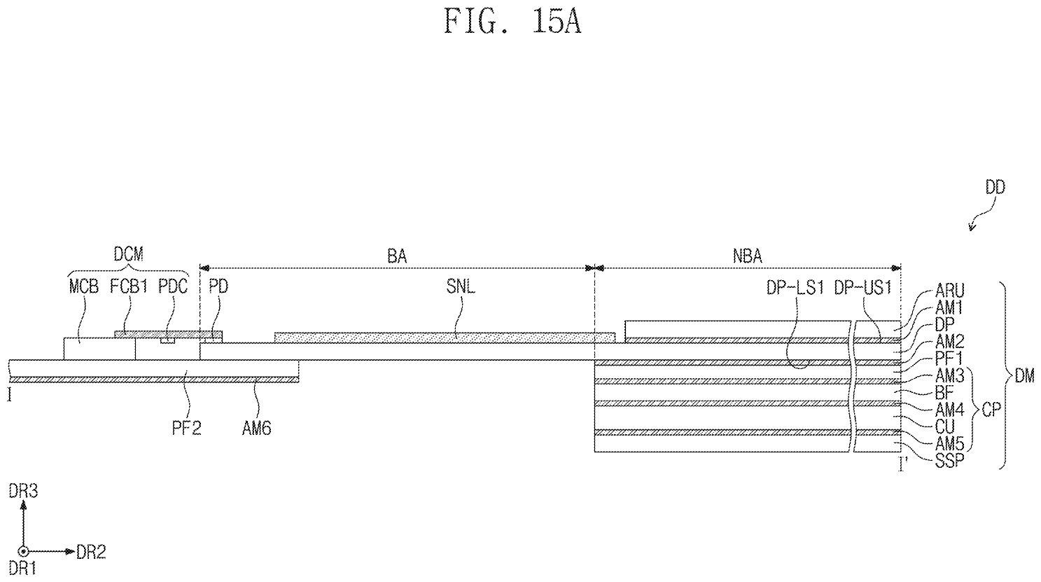

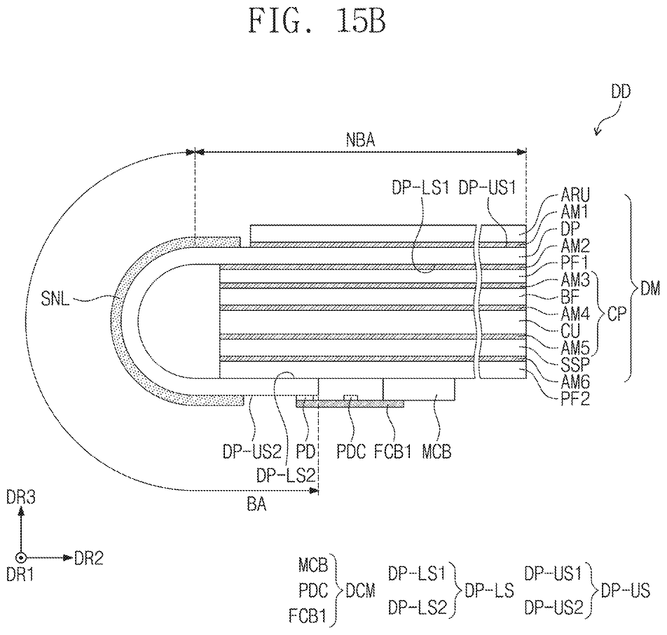

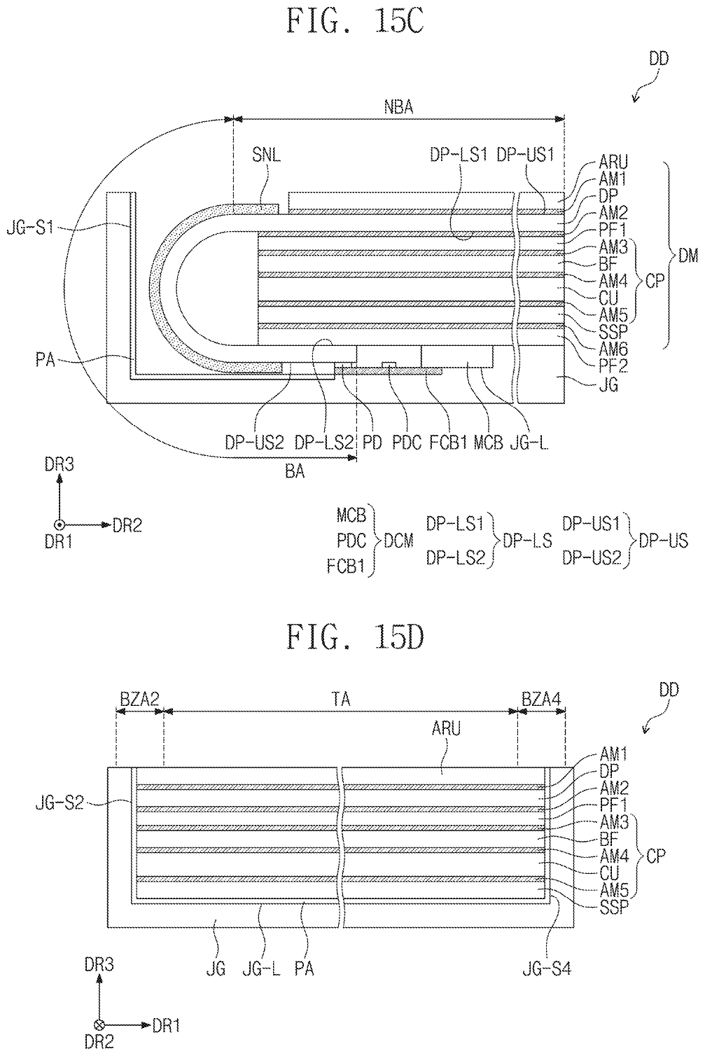

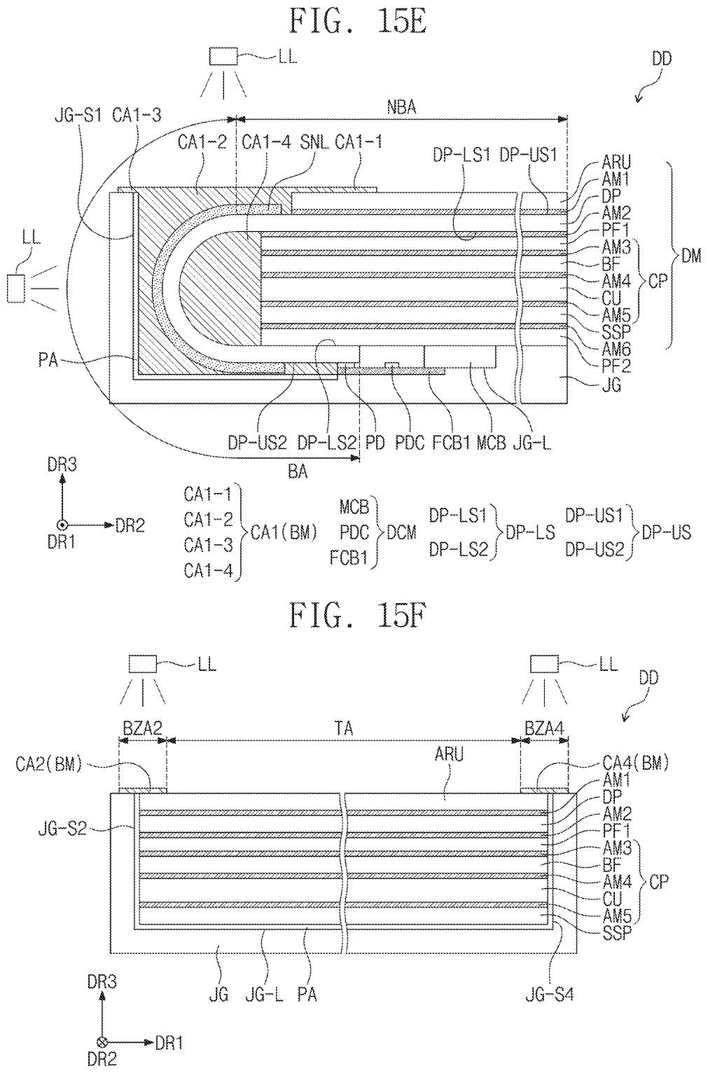

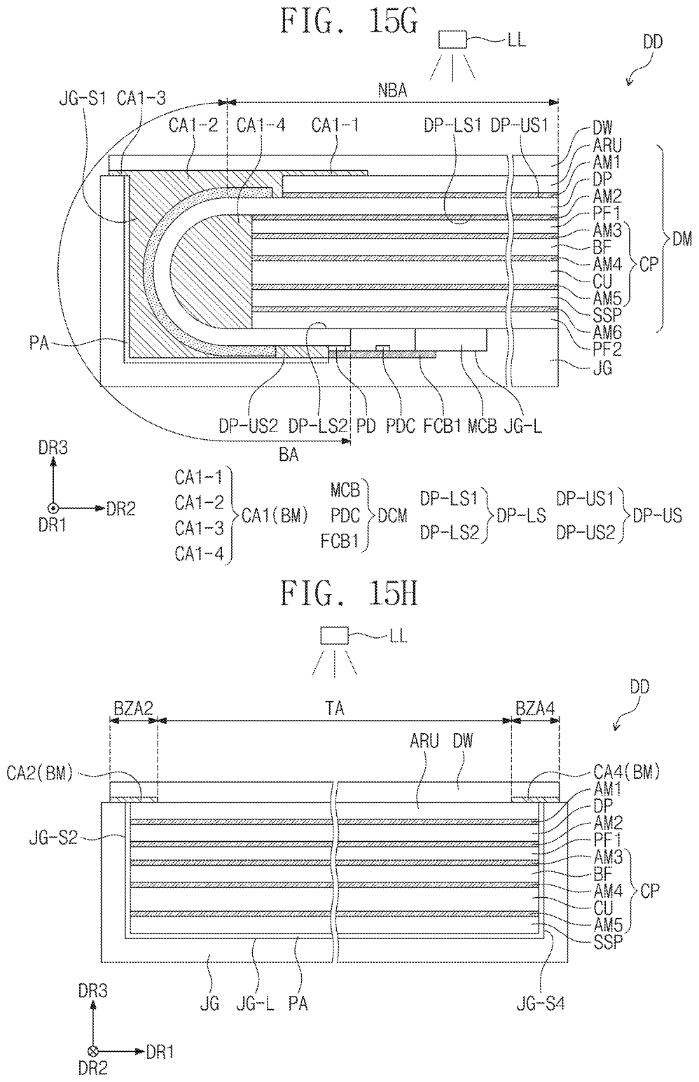

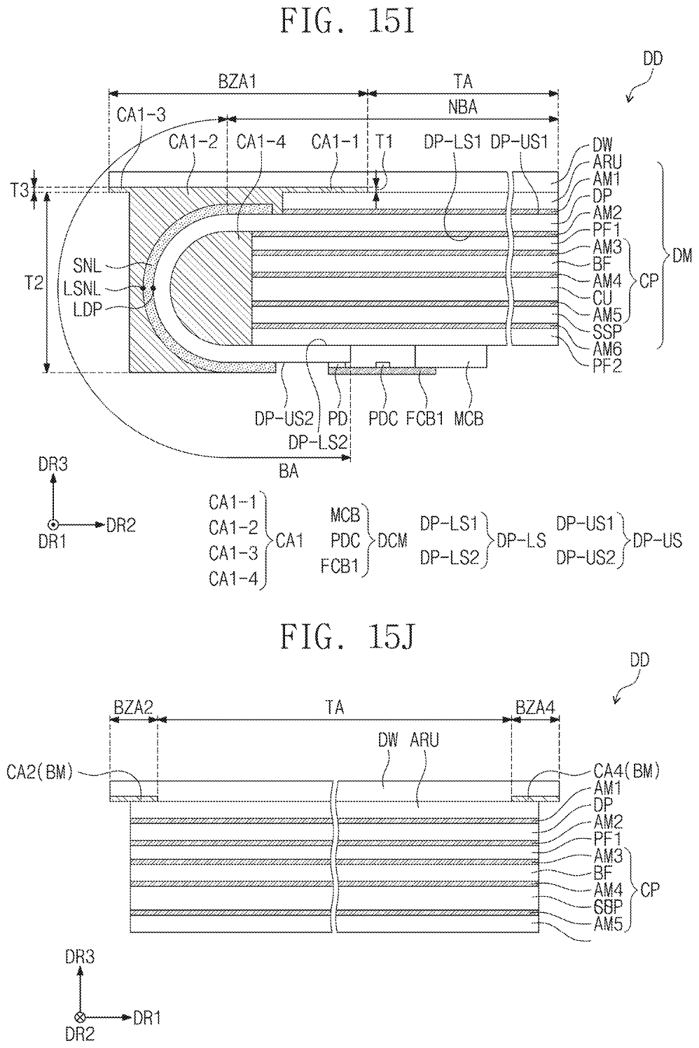

FIGS. 15A to 15J are side views illustrating a method of manufacturing a display device DD according to an embodiment.

In an embodiment and referring to FIG. 15A, a preliminary display device may be prepared, which includes a display panel DP, a first protective layer PF1, a second protective layer PF2, a protective panel CP, a support panel SSP, an optical unit ARU, a bending protective layer SNL, and a driving control module DCM. The detailed structure thereof has been described with reference to FIG. 5A, and therefore, the description thereof will be omitted.

In an embodiment and referring to FIG. 15B, the bending region BA and the bending protective layer SNL of the display panel DP may be bent. The display panel DP may be bent so that the end portion of the bending region BA may face the rear surface of the display panel DP in the non-bending region NBA. The second protective layer PF2 may be disposed below the support panel SSP.

In an embodiment and referring to FIG. 15C, the preliminary display device that has undergone a bending process may be disposed on a jig JG. A release coating layer PA may be disposed on a first side surface JG-S1 of the jig JG and a lower surface JG-L of the jig JG. A step difference corresponding to the lower surface of the display device DD may be defined on the lower surface JG-L of the jig JG. The release coating layer PA may allow the display device DD to be easily separated from the jig JG in a subsequent process. The release coating layer PA may be coated on a region corresponding to the first light blocking pattern CA1 of FIG. 15E. The first side surface JG-S1 of the jig JG may be spaced apart from the bending protective layer SNL by a predetermined distance in the second direction DR2.

In an embodiment, FIG. 15D is a cross-sectional view along a direction crossing the second bezel region BZA2 and the fourth bezel region BZA4 in a state in which the preliminary display device is disposed on the jig JG as illustrated in FIG. 15C. That is, FIG. 15D is a cross-sectional view along the same direction as that of line II-II′ of FIG. 2B.

In an embodiment, a second side surface JG-S2 of the jig JG may have a shape corresponding to the shape of the side surface of the display panel DP adjacent to the second bezel region BZA2, the shape of the side surface of the first protective layer PF1, and the shape of the side surface of the protective panel CP. A fourth side surface JG-S4 of the jig JG may have a shape corresponding to the shape of the side surface of the display panel DP adjacent to the fourth bezel region BZA4, the shape of the side surface of the first protective layer PF1, and the shape of the side surface of the protective panel CP. The release coating layer PA and both side surfaces of the display panel DP may come in contact with each other.

In an embodiment and referring to FIG. 15E, a first light blocking pattern CA1 may be formed, which comes in contact with each side surface of the first and second protective layers PF1 and PF2 and is partially disposed on the upper surface DP-US of the display panel DP. The first light blocking pattern CA1 may come in contact with the bending region BA of the display panel DP. The first light blocking pattern CA1 may be formed by filling the jig JG with a light blocking material and curing the light blocking material using light generated by an exposure device LL. The light blocking material may be a black resin that blocks light. The light blocking material may fill up to positions corresponding to the (1-1)-th to (1-4)-th light blocking patterns CA1-1 to CA1-4, respectively, described above.

In an embodiment, since the first light blocking pattern CA1 is formed to be thick, light generated by the exposure device LL located above may not reach the entire first light blocking pattern CA1. Therefore, by disposing the exposure device LL on a side of the jig JG, it is possible to make light reach the entire first light blocking pattern CA1. In this case, the jig JG may contain a material through which light such as ultraviolet rays generated by the exposure device LL may pass. For example, the jig JG may contain quartz.

In an embodiment and referring to FIG. 15F, a second light blocking pattern CA2 and a fourth light blocking pattern CA4 may be formed to correspond to the second bezel region BZA2 and the fourth bezel region BZA4, respectively. The second light blocking pattern CA2 and the fourth light blocking pattern CA4 may be formed in the same manner as the first light blocking pattern CA1 described above.

In an embodiment and referring to FIG. 15G, a coating window DW containing a resin material may be formed on the first light blocking pattern CA1 and the optical unit ARU. The coating window DW may be formed by applying a coating liquid containing a resin material on the first light blocking pattern CA1 and the optical unit ARU and then curing the applied coating liquid. As the coating window DW is formed this way, the manufacturing process thereof may be simplified by omitting a separate lamination process, an optical clear adhesive (OCA) forming process for bonding, and the like, thereby improving process reliability and reducing costs.

In an embodiment and referring to FIG. 15H, a coating window DW may be formed on the optical unit ARU, the second light blocking pattern CA2 and the fourth light blocking pattern CA4. In this case, the coating window DW may be formed in the same manner as described in FIG. 15G.

In an embodiment and referring to FIGS. 151 and 15J, the jig JG may be removed from the display device DD.

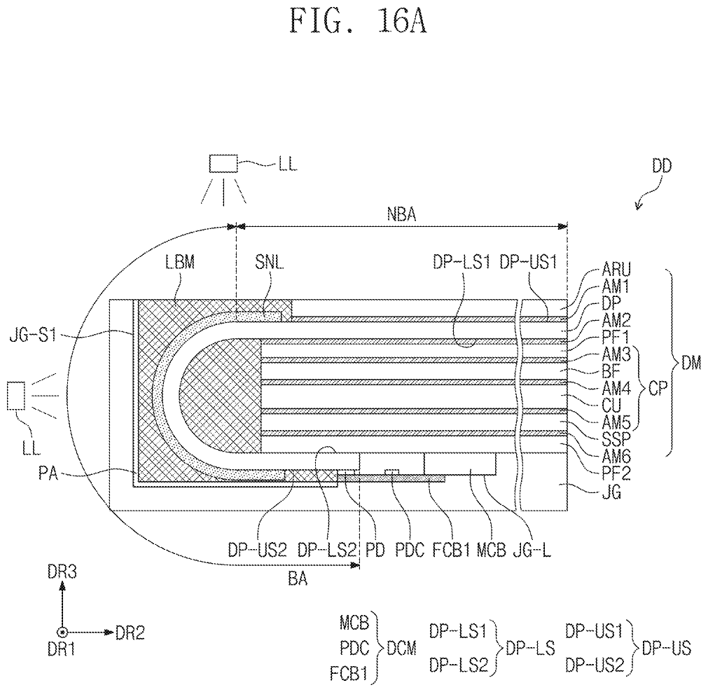

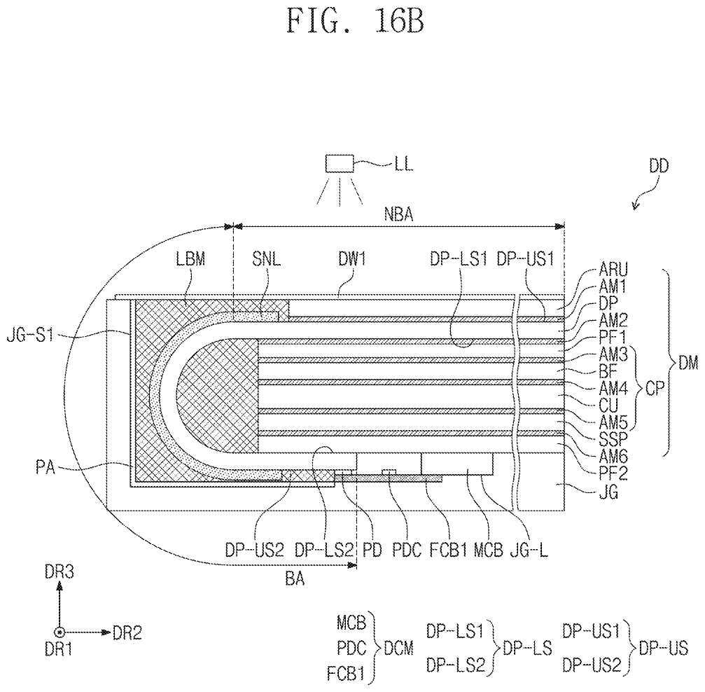

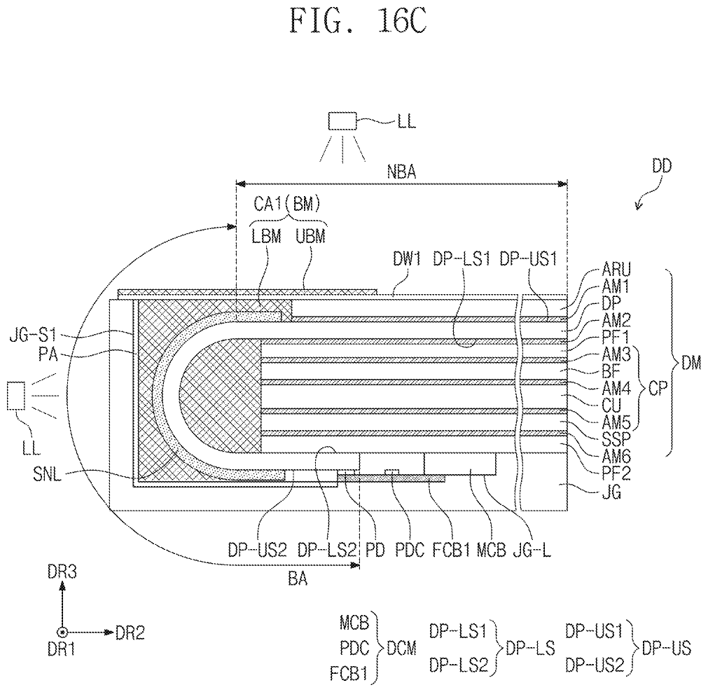

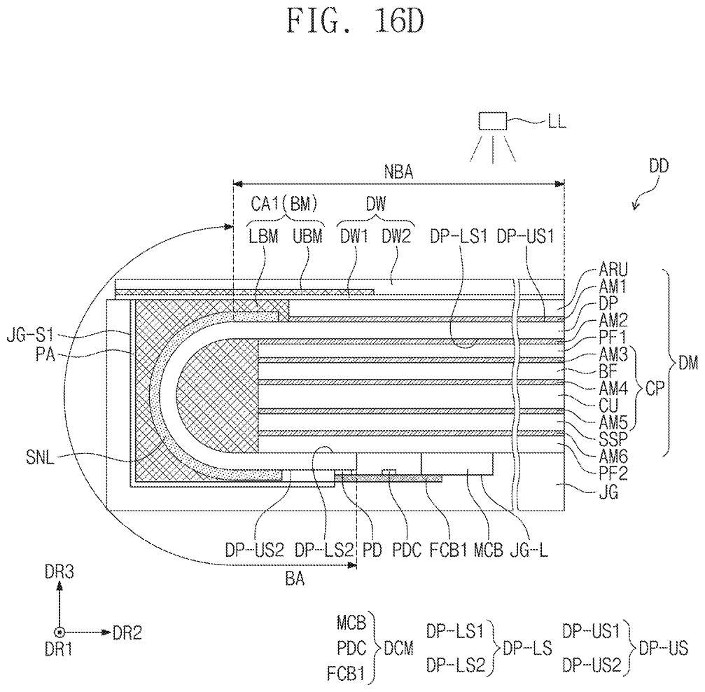

FIGS. 16A to 16D are side views illustrating some steps of the method of manufacturing the display device according to an embodiment. The descriptions of the same components as those of the display device DD described with reference to FIG. 7 will be omitted.

In an embodiment and referring to FIG. 16A, a lower light blocking pattern LBM may be formed, which comes in contact with a side surface of each of the first and second protective layers PF1 and PF2 and is partially disposed on the upper surface DP-US of the display panel DP. The lower light blocking pattern LBM may come in contact with the bending protective layer SNL and the bending region BA of the display panel DP. The lower light blocking pattern LBM may have a flat upper surface. The lower light blocking pattern LBM may be formed by making a filling with a filling material and then curing the filling material using light generated by the exposure device LL.

In an embodiment and referring to FIG. 16B, a first coating window DW1 may be formed on the lower light blocking pattern LBM. The first coating window DW1 may have a lower modulus value than a second coating window DW2 to be described later. The first coating window DW1 may be formed by applying a coating liquid containing a resin material and then curing the applied coating liquid using light generated by the exposure device LL.

In an embodiment and referring to FIG. 16C, an upper light blocking pattern UBM may be formed, which is disposed above the lower light blocking pattern LBM and which contains a material different from that of the lower light blocking pattern LBM. The upper light blocking pattern UBM may contain a black resin that blocks light. The upper light blocking pattern UBM may be formed by applying a coating liquid containing a resin material different from that of the first coating window DW1 and then curing the applied coating liquid using light generated by the exposure device LL.

In an embodiment and referring to FIG. 16D, a second coating window DW2 containing a resin material may be formed on the upper light blocking pattern UBM and the optical unit ARU. The second coating window DW2 may have a higher modulus value than the first coating window DW1. The second coating window DW2 may be formed in the same manner as the first coating window DW1.

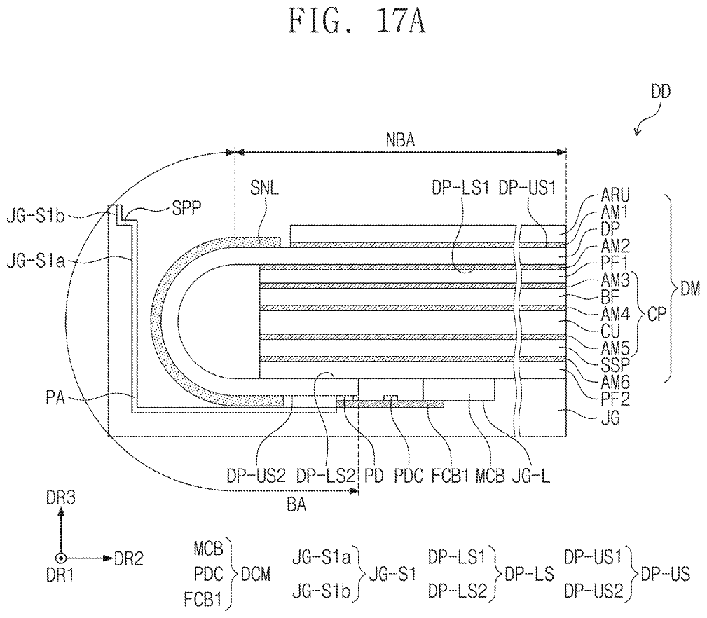

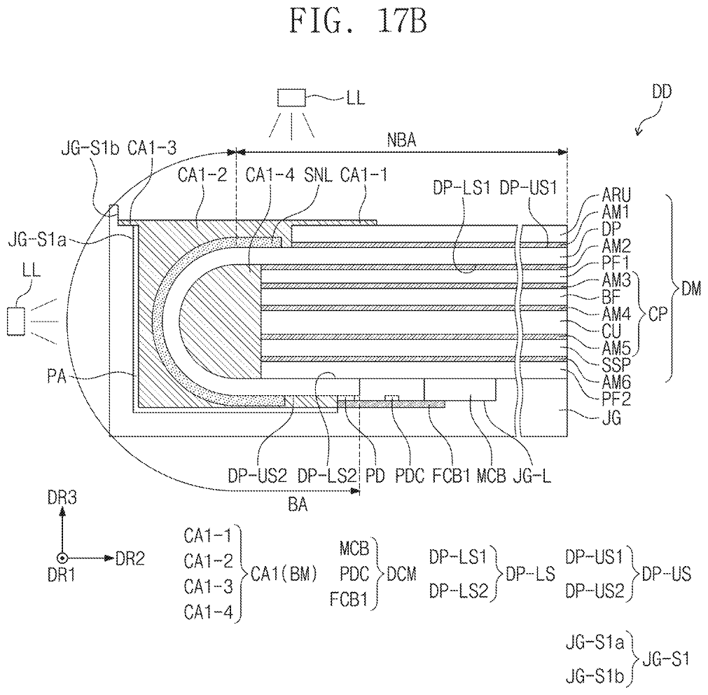

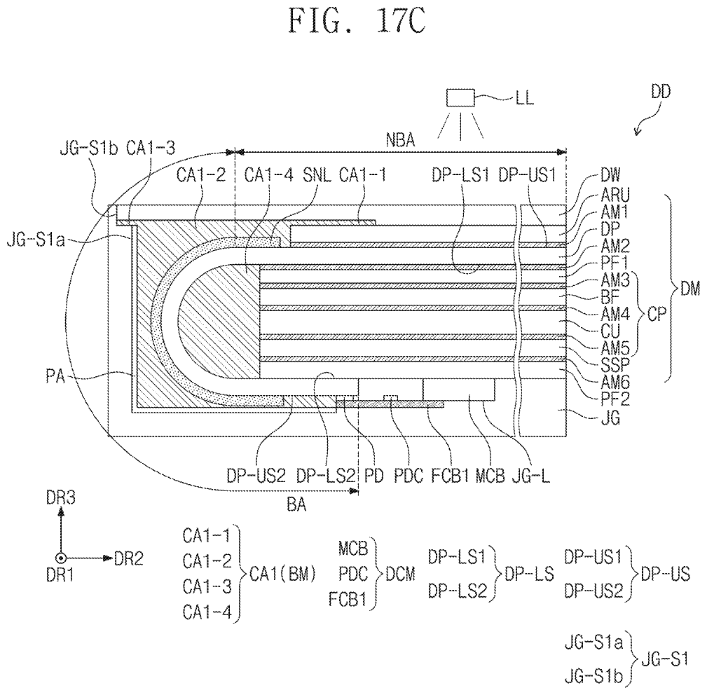

FIGS. 17A to 17C are side views illustrating some steps of the method of manufacturing the display device according to an embodiment. The contents of FIGS. 17A to 17C may be respectively equal to those described in FIGS. 15C, 15E, and 15G except that a step difference SPP is formed in the jig JG. Therefore, the duplicate description thereof will be omitted.

In an embodiment and referring to FIGS. 17A to 17C, a step difference SPP may be defined between a (1-1)-th side surface JG-Sla and a (1-2)-th side surface JG-S1b of the jig JG. The step difference SPP corresponding to the side surface of the coating window DW may be defined on the first side surface JG-S1 of the jig JG. Such a side surface structure of the jig JG may serve as a guide in forming an outer side surface of the first light blocking pattern CA1 and an outer side surface of the coating window DW.

In an embodiment, when the first light blocking pattern CA1 is formed, the outer side surface of the first light blocking pattern CA1 may be formed in a shape corresponding to the step difference SPP of the jig JG. When the coating window DW is formed, the outer side surface of the coating window DW may be formed in a shape corresponding to the (1-2)-th side surface JG-S1b of the jig.

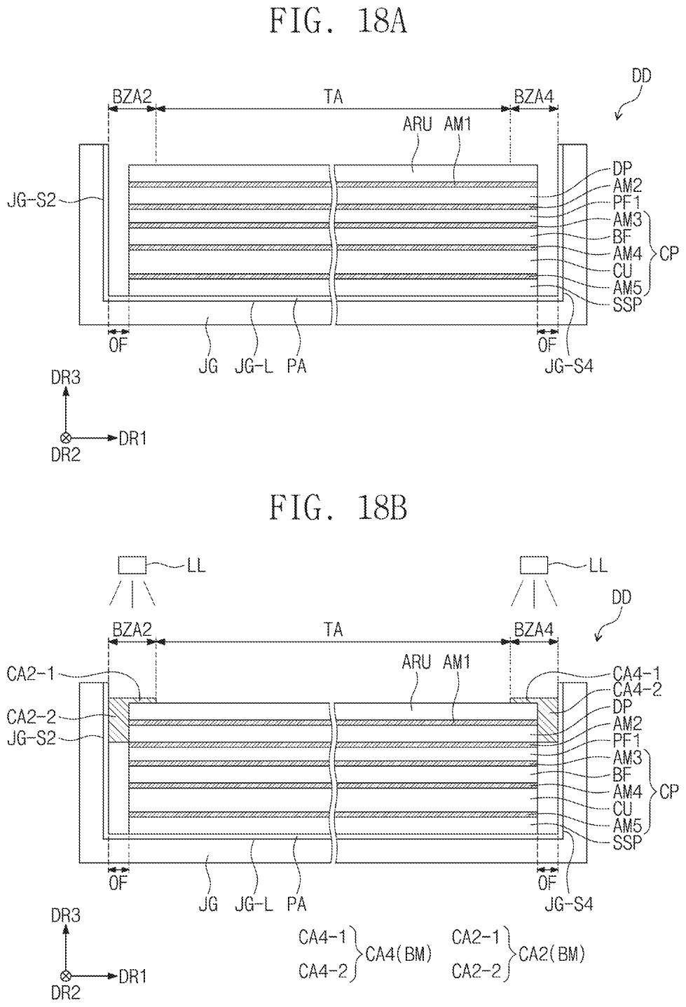

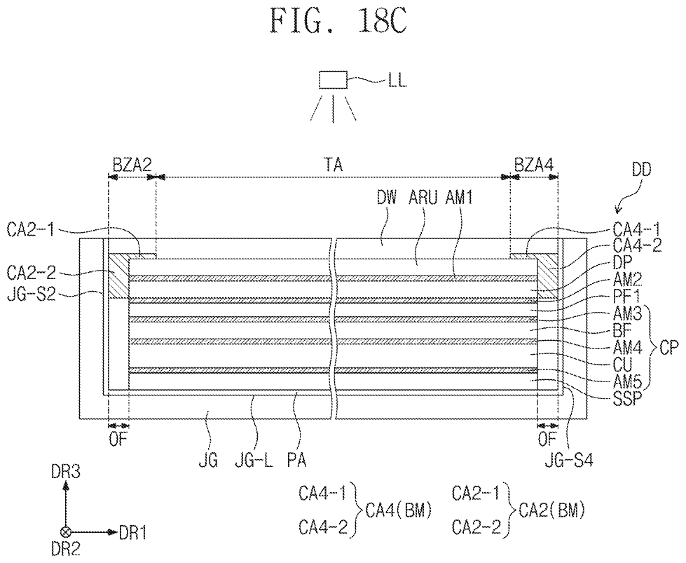

FIGS. 18A to 18C are side views illustrating some steps of the method of manufacturing the display device according to an embodiment. FIGS. 18A to 18C may be respectively equal to FIGS. 15D, 15F, and 15H except for a separation space OF between the jig JG and the side surface of the display device DD, and therefore, the duplicate description thereof will be omitted.

In an embodiment and referring to FIGS. 18A to 18C, the second and fourth side surfaces JG-S2 and JG-S4 of the jig JG may be spaced apart from the side surface of the display device DD so that the shapes of the second light blocking pattern CA2 and the fourth light blocking pattern CA4 may be extended. When the second and fourth light blocking patterns CA2 and CA4 are formed, the separation space OF between the side surface of the display device DD and the jig JG is filled with a light blocking material, and then the light blocking material may be cured using light generated by the exposure device LL. Accordingly, a (2-2)-th light blocking pattern CA2-2 and a (4-2)-th light blocking pattern CA4-2 may be formed, which respectively extend in the third direction DR3 from the (2-1)-th light blocking pattern CA2-1 and the (4-1)-th light blocking pattern CA4-1. The (2-2)-th light blocking pattern CA2-2 and the (4-2)-th light blocking pattern CA4-2 may cover the side surfaces of the display panel DP.

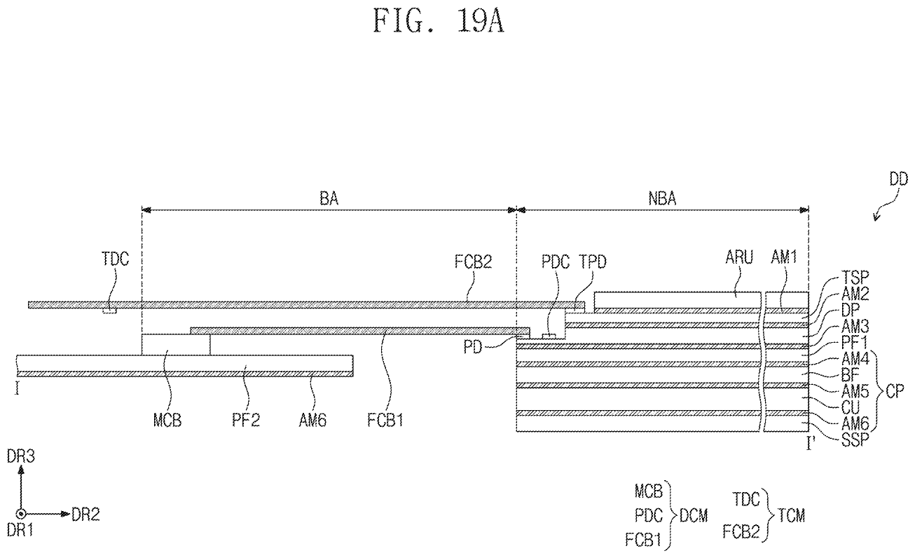

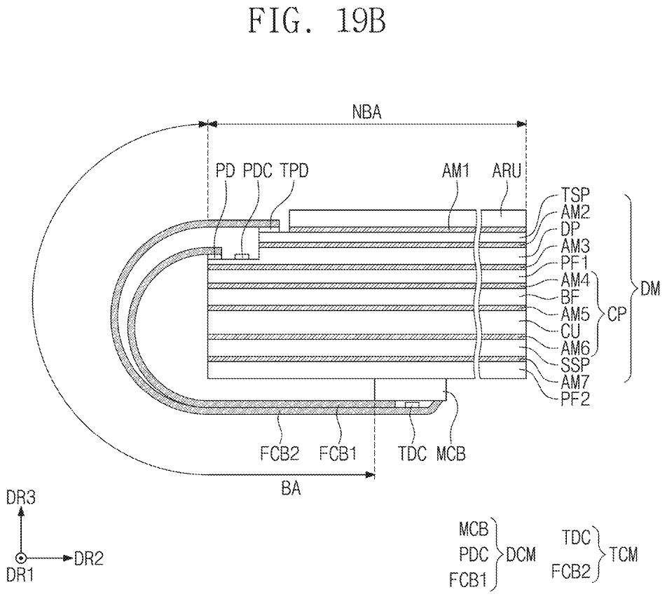

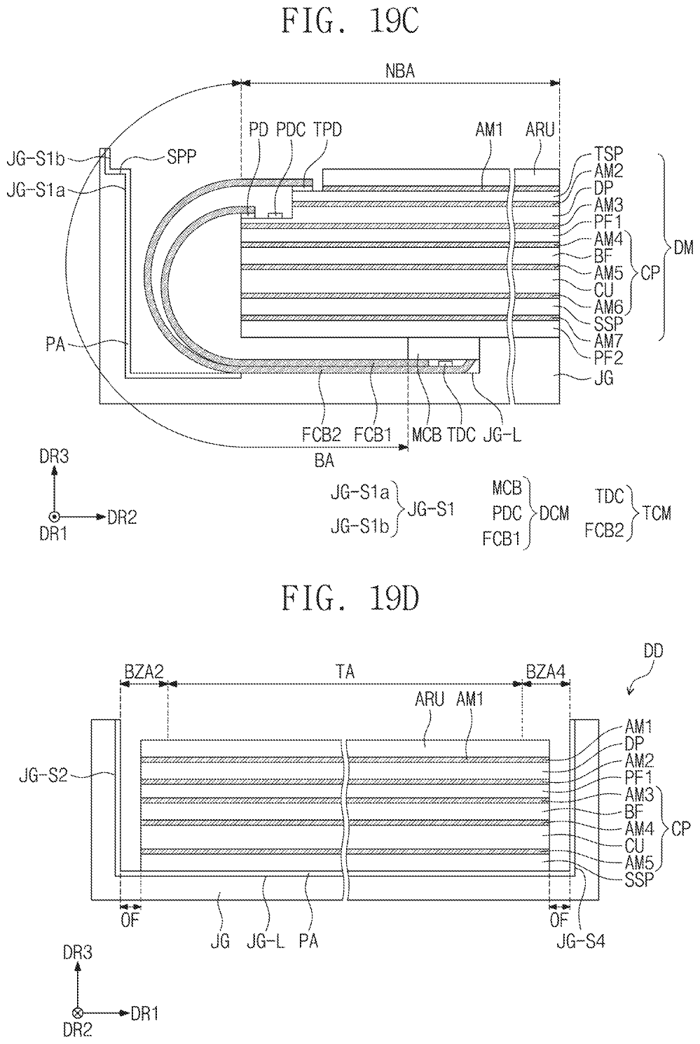

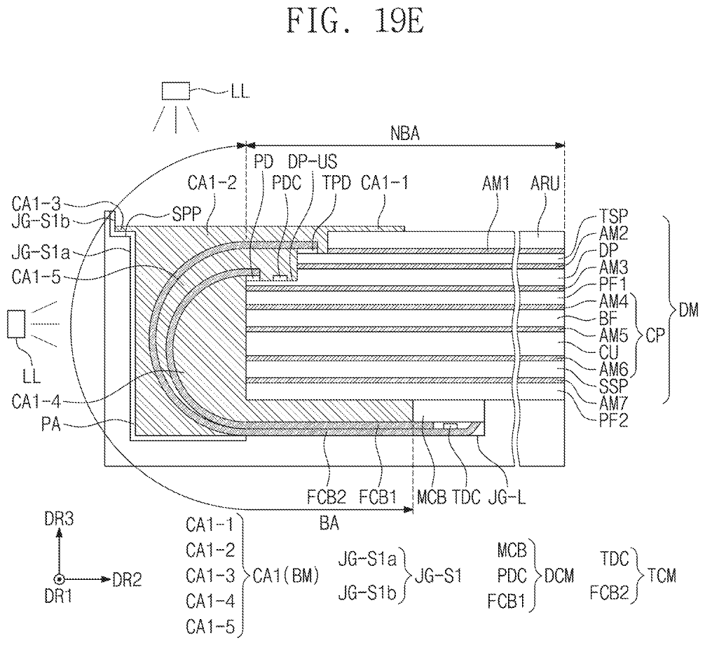

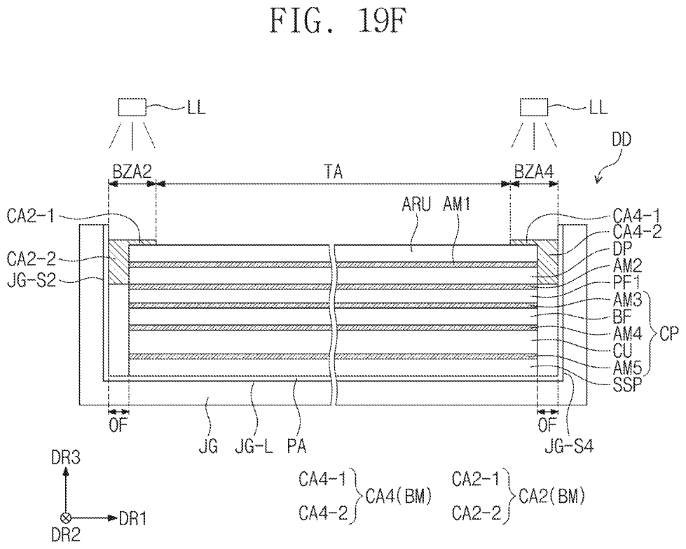

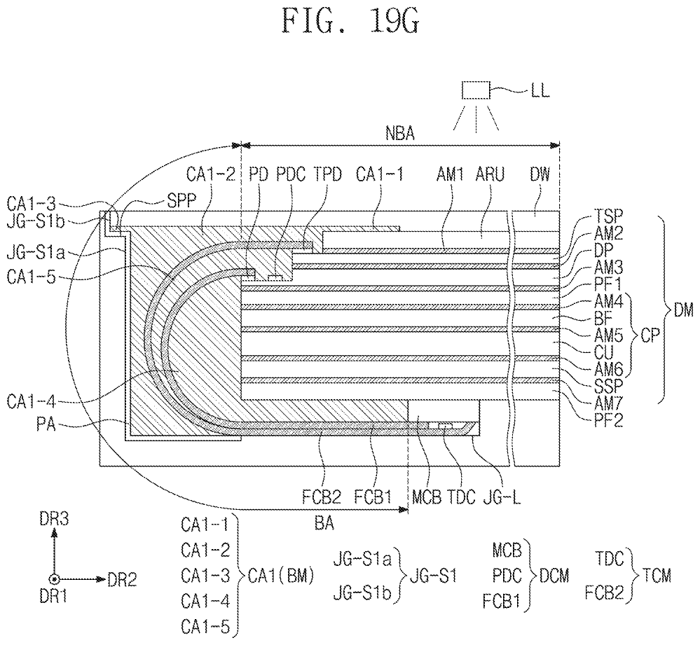

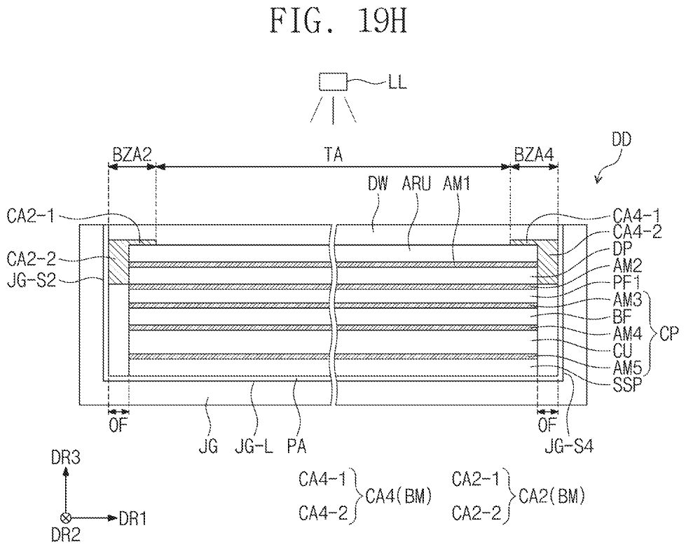

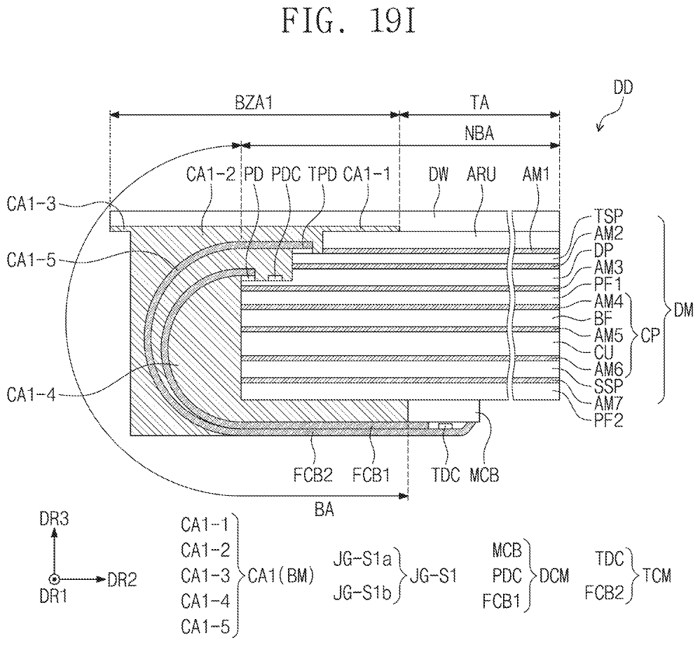

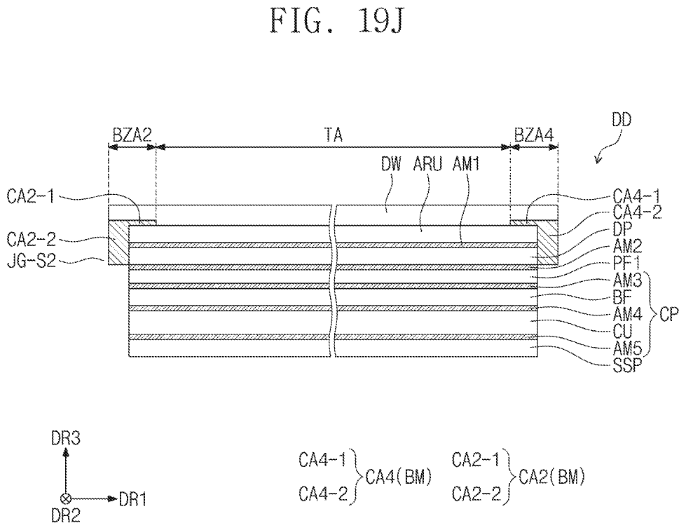

FIGS. 19A to 19J are side views illustrating the method of manufacturing the display device DD according to an embodiment.

In an embodiment and referring to FIG. 19A, the preliminary display device may be prepared, which includes a display panel DP, a first protective layer PF1, a second protective layer PF2, a protective panel CP, a support panel SSP, an optical unit ARU, a touch sensing panel TSP, a touch control unit TCM, and a driving control module DCM. The detailed structure thereof has been described with reference to FIG. 12A, and therefore, the description thereof will be omitted.

In an embodiment and referring to FIG. 19B, the first circuit board FCB1 and the second circuit board FCB2 may be bent. The first circuit board FCB1 and the second circuit board FCB2 may be bent so that the end portion of each of the first circuit board FCB1 and the second circuit board FCB2 may face the rear surface of the display panel DP in the non-bending region NBA. The second protective layer PF2 may be disposed below the support panel SSP.

In an embodiment and referring to FIG. 19C, the preliminary display device that has undergone a bending process may be disposed on the jig JG. A release coating layer PA may be disposed on the first side surface JG-S1 of the jig JG and the lower surface JG-L of the jig JG. The first side surface JG-S1 of the jig JG may be spaced apart from the bending protective layer SNL by a predetermined distance in the second direction DR2. A step difference SPP corresponding to the shape of the side surface of the coating window DW (see FIG. 19G) may be defined at the boundary between the (1-1)-th side surface JG-Sla and the (1-2)-th side surface JG-S1b of the jig JG.

In an embodiment, FIG. 19D is a cross-sectional view along a direction crossing the second bezel region BZA2 and the fourth bezel region BZA4 in a state in which the preliminary display device is disposed on the jig JG as illustrated in FIG. 19C. That is, FIG. 19D is a cross-sectional view along the same direction as that of line II-II′ in FIG. 2B.

In an embodiment, the second side surface JG-S2 of the jig JG may have a shape corresponding to the shape of the side surface of the display panel DP adjacent to the second bezel region BZA2, the shape of the side surface of the first protective layer PF1, and the shape of the side surface of the protective panel CP. The fourth side surface JG-S4 of the jig JG may have a shape corresponding to the shape of the side surface of the display panel DP adjacent to the fourth bezel region BZA4, the shape of the side surface of the first protective layer PF1, and the shape of the side surface of the protective panel CP. Each of the second side surface JG-S2 and the fourth side surface JG-S4 may be spaced apart from the side surface of the display panel DP by a separation space OF.

In an embodiment and referring to FIG. 19E, a first light blocking pattern CA1 may be formed, which comes in contact with the side surface of each of the first and second protective layers PF1 and PF2 and is partially disposed on the upper surface DP-US of the display panel DP. The first light blocking pattern CA1 may come in contact with the bent portion of the first circuit board FCB1 and the bent portion of the second circuit board FCB2. The first light blocking pattern CA1 may be formed by filling the jig JG with a light blocking material and then curing the light blocking material using light generated by the exposure device LL. The light blocking material may be a black resin that blocks light. The light blocking material may fill up to positions corresponding to the (1-1)-th to (1-5)-th light blocking patterns CA1-1 to CA1-5, respectively, described above.

In an embodiment and referring to FIG. 19F, a second light blocking pattern CA2 and a fourth light blocking pattern CA4 may be formed to correspond to the second bezel region BZA2 and the fourth bezel region BZA4. In this case, the separation space OF may be filled with a light blocking material, and then the light blocking material may be cured using light generated by the exposure device LL. Accordingly, a (2-2)-th light blocking pattern CA2-2 and a (4-2)-th light blocking pattern CA4-2 may be formed, which respectively extends in the third direction DR3 from the (2-1)-th light blocking pattern CA2-1 and the (4-1)-th light blocking pattern CA4-1. The (2-2)-th light blocking pattern CA2-2 and the (4-2)-th light blocking pattern CA4-2 may cover the side surface of the display panel DP.

In an embodiment and referring to FIG. 19G, a coating window DW containing a resin material may be formed on the first light blocking pattern CA1 and the optical unit ARU. The coating window DW may be formed by applying a coating liquid containing a resin material on the first light blocking pattern CA1 and the optical unit ARU and then curing the applied coating liquid.

In an embodiment and referring to FIG. 19H, a coating window DW may be formed on the optical unit ARU, the second light blocking pattern CA2, and the fourth light blocking pattern CA4. In this case, the coating window DW may be formed in the same manner as described in FIG. 19G.

In an embodiment, referring to FIGS. 191 and 19J, the jig JG may be removed from the display device DD.

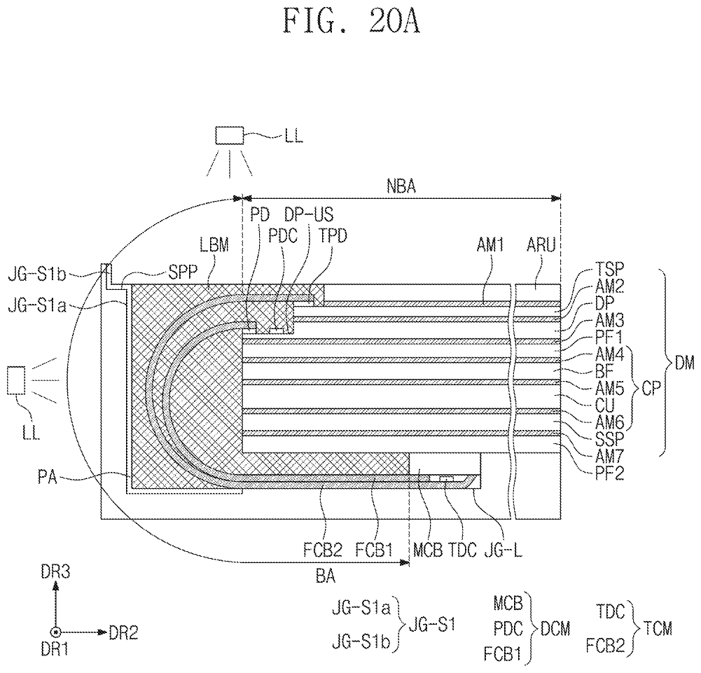

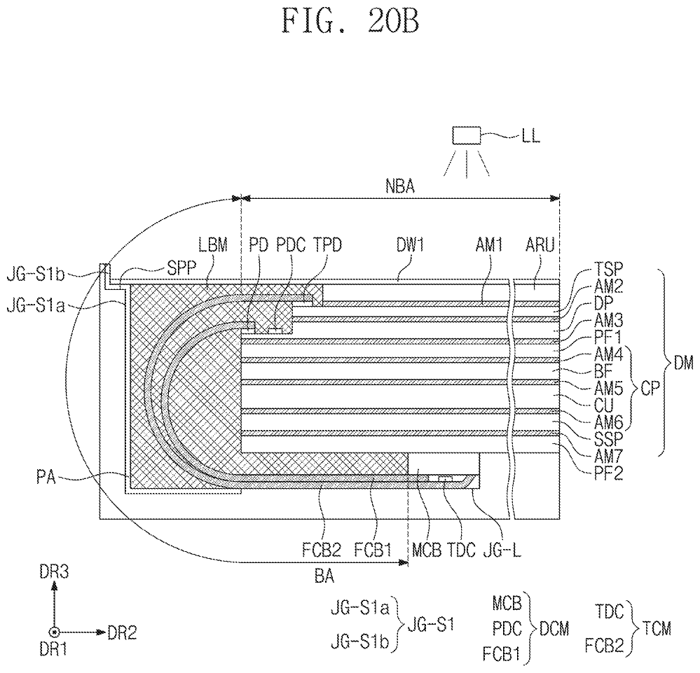

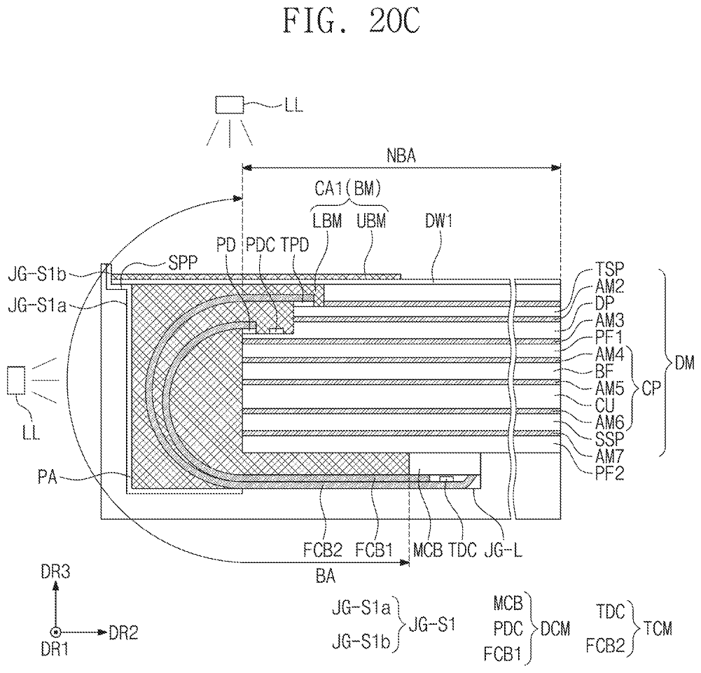

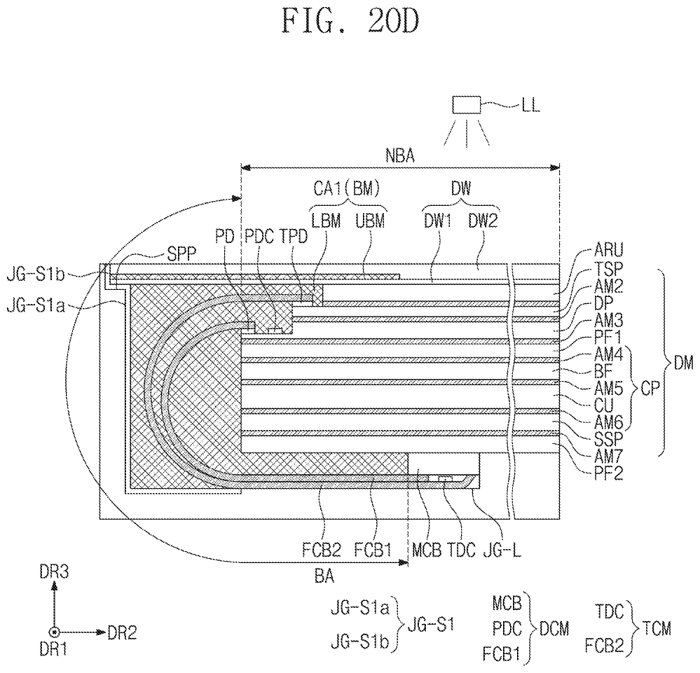

FIGS. 20A to 20D are side views illustrating some steps of the method of manufacturing the display device DD according to an embodiment. The descriptions of the same components as those of the display device DD described with reference to FIG. 14 will be omitted.

In an embodiment and referring to FIG. 20A, a lower light blocking pattern LBM may be formed, which comes in contact with a side surface of each of the first and second protective layers PF1 and PF2 and is partially disposed on the upper surface DP-US of the display panel DP. The lower light blocking pattern LBM may come in contact with the first circuit board FCB1 and the second circuit board FCB2. The lower light blocking pattern LBM may have a flat upper surface. The lower light blocking pattern LBM may be formed by making a filling with a filling material and then curing the filling material using light generated by the exposure device LL.

In an embodiment and referring to FIG. 20B, a first coating window DW1 may be formed on the lower light blocking pattern LBM. The first coating window DW1 may have a lower modulus value than a second coating window DW2 to be described later. The first coating window DW1 may be formed by applying a coating liquid containing a resin material and then curing the applied coating liquid using light generated by the exposure device LL.

In an embodiment, referring to FIG. 20C, an upper light blocking pattern UBM may be formed, which is disposed above the lower light blocking pattern LBM and contains a material different from that of the lower light blocking pattern LBM. The upper light blocking pattern UBM may contain a black resin that blocks light. The upper light blocking pattern UBM may be formed by applying a coating liquid containing a resin material different from that of the first coating window DW1 and then curing the applied coating liquid using light generated by the exposure device LL.

In an embodiment and referring to FIG. 20D, a second coating window DW2 containing a resin material may be formed on the upper light blocking pattern UBM and the optical unit ARU. The second coating window DW2 may have a higher modulus value than the first coating window DW1. The second coating window DW2 may be formed in the same manner as the first coating window DW1.

In the display device according to an embodiment, the light blocking pattern is disposed to cover the bending region so that the bending region may not be visually recognized from the outside.

In addition, the light blocking pattern may cover a portion of a side surface of the display panel so as to prevent damage to the display panel from an external impact.

The method of manufacturing the display device according to an embodiment may secure the reliability and economic feasibility of a manufacturing process by simplifying the manufacturing process.

Although the above has been described with reference to embodiments of the invention, those skilled in the art or those of ordinary skill in the art will understand that various modifications and changes can be made to the invention within the scope that does not depart from the spirit and technical field of the invention described in the claims to be described later. Accordingly, the technical scope of the invention should not be limited to the content described in the detailed description of the specification, but should be determined by the claims described hereinafter.

What is claimed is:

1. A display device comprising:
a display panel comprising a non-bending region and a bending region that extends from an end of the non-bending region and that is bent;
a protective layer disposed on a lower surface of the display panel;
a light blocking pattern overlapping the bending region in a plan view, partially disposed on an upper surface of the display panel, and contacting a side surface of the protective layer and the bending region; and
a coating window disposed directly on the light blocking pattern and comprising a resin material.

2. The display device of claim 1, wherein the light blocking pattern covers a bent portion of the bending region.

3. The display device of claim 1, wherein the light blocking pattern comprises:
a first light blocking pattern disposed between the bending region and a side surface of the protective layer; and
a second light blocking pattern disposed on the bending region and adjacent to an outside portion of the bending region.

4. The display device of claim 1, further comprising an optical unit disposed between the display panel and the coating window and overlapping the non-bending region,
wherein the coating window is disposed directly on the optical unit.

5. The display device of claim 4, wherein a portion of the light blocking pattern is disposed directly on the optical unit.

6. The display device of claim 1, further comprising a bending protective layer, which is disposed on the display panel and which is bent together with the bending region,
wherein the light blocking pattern is in contact with the bending protective layer.

7. The display device of claim 1, wherein the light blocking pattern covers a side surface of the display panel on a cross section.

8. The display device of claim 1, wherein the light blocking pattern comprises:
a lower light blocking pattern contacting the bending region and a side surface of the protective layer; and
an upper light blocking pattern disposed above the lower light blocking pattern and comprising a material different from that of the lower light blocking pattern.

9. The display device of claim 8, wherein the coating window comprises:
a first coating window directly disposed between the lower light blocking pattern and the upper light blocking pattern and having a first modulus value; and
a second coating window disposed directly on the upper light blocking pattern and the first coating window and having a second modulus value greater than the first modulus value.

10. A display device comprising:
a display panel comprising a display region and a non-display region surrounding the display region;
a first circuit board which is connected to the display panel and which is bent;
a protective layer disposed on a lower surface of the display panel;
a light blocking pattern overlapping a bent portion of the first circuit board in a plan view, partially disposed on an upper surface of the display panel, and contacting a side surface of the protective layer and a bent portion of the first circuit board; and
a coating window disposed directly on the light blocking pattern and comprising a resin material.

11. The display device of claim 10, wherein the light blocking pattern covers the bent portion of the first circuit board.

12. The display device of claim 10, wherein the light blocking pattern covers a side surface of the display panel on a cross section.

13. The display device of claim 10, further comprising:
a touch sensing panel disposed on the display panel and configured to sense an input signal; and
a second circuit board which is bent, connected to the touch sensing panel, and configured to transmit the input signal.

14. The display device of claim 13, wherein the light blocking pattern comprises:
a first light blocking pattern disposed between a side surface of the protective layer and the first circuit board;
a second light blocking pattern disposed between the first circuit board and the second circuit board; and
a third light blocking pattern disposed on the second circuit board and adjacent to an outside of the second circuit board.

15. A method for manufacturing a display device, the method comprising:
preparing a preliminary display device comprising a display panel and a protective layer disposed on a lower surface of the display panel;
bending the display panel portion or a first circuit board coupled to the display panel;
disposing a bent preliminary display device on a jig;
forming a light blocking pattern in contact with a side surface of the protective layer, partially disposed on an upper surface of the display panel, and in contact with the display panel portion or the first circuit board;
providing a resin material on the light blocking pattern; and
forming a first coating window by curing the resin material.

16. The method of claim 15, wherein the forming of the light blocking pattern comprises:
making a filling with a light blocking material which comes in contact with the display panel portion or the first circuit board; and
curing the light blocking material.

17. The method of claim 15, wherein a step difference corresponding to a side surface of the first coating window is defined on one side surface of the jig.

18. The method of claim 15, wherein the jig comprises a material that allows ultraviolet rays to pass therethrough.

19. The method of claim 15, wherein the forming of the light blocking pattern comprises:
forming a lower light blocking pattern contacting the display panel portion or the first circuit board; and
forming an upper light blocking pattern disposed above the lower light blocking pattern and comprising a material different from that of the lower light blocking pattern.

20. The method of claim 19, further comprising forming a second coating window on the lower light blocking pattern, wherein second coating window has a lower modulus value than the first coating window.
